(19) United States
(12) Patent Application Publication
(10) Pub. No.: US 2015/0279815 A1
(43) Pub. Date: Oct. 1, 2015

(54) Semiconductor Device and Method of Forming Substrate Having Conductive Columns

(71) Applicant: STATS ChipPAC, Ltd., Singapore (SG)

(72) Inventors: Byung Tai Do, Singapore (SG); Arnel Trasporto, Singapore (SG); Sung Soo Kim, Singapore (SG)

(73) Assignee: STATS ChipPAC, Ltd., Singapore (SG)

(21) Appl. No.: 14/228,769

(22) Filed: Mar. 28, 2014

(51) Int. Cl. H01L 25/065; H01L 23/498; H01L 21/48; H01L 25/00; H01L 23/00

(52) U.S. Cl. CPC H01L 25/0655; H01L 25/50; H01L 24/81; H01L 24/11; H01L 24/17; H01L 21/4853; H01L 23/49838; H01L 21/4857; H01L 21/486; H01L 23/49827; H01L 23/49822; H01L 2224/11334; H01L 2224/1134; H01L 2224/1155; H01L 2224/16113; H01L 2224/16227

(57) ABSTRACT

A semiconductor device has a first conductive layer disposed over a carrier. A second conductive layer is formed over a first surface of the first conductive layer. A first insulating layer is formed over the first and second conductive layers. A third conductive layer is formed over the first insulating layer. A second insulating layer is formed over the third conductive layer. The carrier is removed to expose the first conductive layer. A portion of the first conductive layer is removed from a second surface of the first conductive layer opposite the first surface to form a plurality of conductive pillars. The conductive pillars include a height of 100 micrometers or greater. The portion of the first conductive layer is removed using an etching process. The conductive pillars are disposed over a first semiconductor package. A semiconductor die or second semiconductor package is disposed over the second conductive layer.

### FIELD OF THE INVENTION

The present invention relates in general to semiconductor devices and, more particularly, to a semiconductor device and method of forming a substrate including conductive columns.

### BACKGROUND OF THE INVENTION

Semiconductor devices are commonly found in modern electronic products. Semiconductor devices vary in the number and density of electrical components. Discrete semiconductor devices generally contain one type of electrical component, e.g., light emitting diode (LED), small signal transistor, resistor, capacitor, inductor, and power metal oxide semiconductor field effect transistor (MOSFET). Integrated semiconductor devices typically contain hundreds to millions of electrical components. Examples of integrated semiconductor devices include microcontrollers, microprocessors, charged-coupled devices (CCDs), solar cells, and digital micro-mirror devices (DMDs).

Semiconductor devices perform a wide range of functions such as signal processing, high-speed calculations, transmitting and receiving electromagnetic signals, controlling electronic devices, transforming sunlight to electricity, and creating visual projections for television displays. Semiconductor devices are found in the fields of entertainment, communications, power conversion, networks, computers, and consumer products. Semiconductor devices are also found in military applications, aviation, automotive, industrial controllers, and office equipment.

Semiconductor devices exploit the electrical properties of semiconductor materials. The structure of semiconductor material allows the material's electrical conductivity to be manipulated by the application of an electric field or base current or through the process of doping. Doping introduces impurities into the semiconductor material to manipulate and control the conductivity of the semiconductor device.

A semiconductor device contains active and passive electrical structures. Active structures, including bipolar and field effect transistors, control the flow of electrical current. By varying levels of doping and application of an electric field or base current, the transistor either promotes or restricts the flow of electrical current. Passive structures, including resistors, capacitors, and inductors, create a relationship between voltage and current necessary to perform a variety of electrical functions. The passive and active structures are electrically connected to form circuits, which enable the semiconductor device to perform high-speed operations and other useful functions.

Semiconductor devices are generally manufactured using two complex manufacturing processes, i.e., front-end manufacturing, and back-end manufacturing, each involving potentially hundreds of steps. Front-end manufacturing involves the formation of a plurality of die on the surface of a semiconductor wafer. Each semiconductor die is typically identical and contains circuits formed by electrically connecting active and passive components. Back-end manufacturing involves singulating individual semiconductor die from the finished wafer and packaging the die to provide structural support and environmental isolation. The term “semiconductor die” as used herein refers to both the singular and plural form of the words, and accordingly, can refer to both a single semiconductor device and multiple semiconductor devices.

One goal of semiconductor manufacturing is to produce smaller semiconductor devices. Smaller devices typically consume less power, have higher performance, and can be produced more efficiently. In addition, smaller semiconductor devices have a smaller footprint, which is desirable for smaller end products. A smaller semiconductor die size can be achieved by improvements in the front-end process resulting in semiconductor die with smaller, higher density active and passive components. Back-end processes may result in semiconductor device packages with a smaller footprint by improvements in electrical interconnection and packaging materials.

One approach to achieving the objectives of greater integration and smaller semiconductor devices is to focus on 3D packaging technologies including package-on-package (PoP). A common semiconductor device arrangement includes an upper semiconductor package stacked over a lower semiconductor package to form a PoP structure. Upper and lower semiconductor packages often require additional interconnection between packages. Further, stacked PoP devices require fine pitch vertical interconnections. Vertical interconnections formed by plating methods increase the cost of the semiconductor device. The process of forming interconnect structures by plating methods is also limited in the height of the interconnect structures that can be achieved.

### SUMMARY OF THE INVENTION

A need exists for a cost effective process of forming an interposer including conductive columns for vertical interconnect. Accordingly, in one embodiment, the present invention is a method of making a semiconductor device comprising the steps of providing a first conductive layer, forming a second conductive layer over a first surface of the first conductive layer, forming a first insulating layer over the first and second conductive layers, and removing a portion of the first conductive layer from a second surface opposite the first surface to form conductive pillars.

In another embodiment, the present invention is a method of making a semiconductor device comprising the steps of providing a first conductive layer, forming a second conductive layer over the first conductive layer, forming a first insulating layer over the second conductive layer, and removing a portion of the first conductive layer to form a conductive pillar.

In another embodiment, the present invention is a method of making a semiconductor device comprising the steps of providing a first conductive layer, forming a second conductive layer over the first conductive layer, and removing a portion of the first conductive layer to form a conductive pillar.

In another embodiment, the present invention is a semiconductor device comprising a first conductive layer. A first insulating layer is formed over a first surface of the first conductive layer. A conductive pillar is formed over a second surface of the first conductive layer opposite the first surface.

### BRIEF DESCRIPTION OF THE DRAWINGS

FIG. 1 illustrates a printed circuit board (PCB) with different types of packages mounted to a surface of the PCB;

FIGS. 2a-2e illustrate a semiconductor wafer with a plurality of semiconductor die separated by a saw street;

FIGS. 3a-3k illustrate a method of forming a substrate having conductive columns;

FIGS. 4a-4b illustrate a method of forming a semiconductor package including a conductive column substrate;

FIGS. 5a-5b illustrate another method of forming a semiconductor package including a conductive column substrate;

FIGS. 6a-6l illustrate another method of forming a substrate having conductive columns;

FIG. 7 illustrates a semiconductor package including a conductive column substrate;

FIG. 8 illustrates another semiconductor package including a conductive column substrate;

FIGS. 9a-9p illustrate another method of forming a substrate having conductive columns using a double-sided process;

FIG. 10 illustrates another semiconductor package including a conductive column substrate; and

FIG. 11 illustrates another semiconductor package including a conductive column substrate.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, those skilled in the art will appreciate that the description is intended to cover alternatives, modifications, and equivalents as may be included within the spirit and scope of the invention as defined by the appended claims and the claims' equivalents as supported by the following disclosure and drawings.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Passive and active components are formed over the surface of the semiconductor wafer by a series of process steps including doping, deposition, photolithography, etching, and planarization. Doping introduces impurities into the semiconductor material by techniques such as ion implantation or thermal diffusion. The doping process modifies the electrical conductivity of semiconductor material in active devices by dynamically changing the semiconductor material conductivity in response to an electric field or base current. Transistors contain regions of varying types and degrees of doping arranged as necessary to enable the transistor to promote or restrict the flow of electrical current upon the application of the electric field or base current.

Active and passive components are formed by layers of materials with different electrical properties. The layers can be formed by a variety of deposition techniques determined in part by the type of material being deposited. For example, thin film deposition can involve chemical vapor deposition (CVD), physical vapor deposition (PVD), electrolytic plating, and electroless plating processes. Each layer is generally patterned to form portions of active components, passive components, or electrical connections between components.

Back-end manufacturing refers to cutting or singulating the finished wafer into the individual semiconductor die and then packaging the semiconductor die for structural support and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are mounted to a package substrate that includes pins or contact pads for interconnection with other system components. Contact pads formed over the semiconductor die are then connected to contact pads within the package. The electrical connections can be made with solder bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

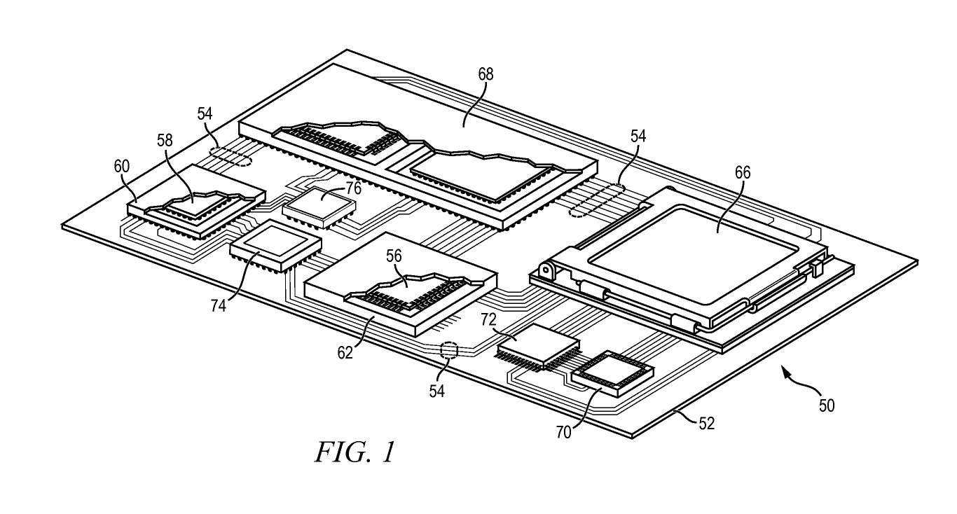

FIG. 1 illustrates electronic device 50 having a chip carrier substrate or PCB 52 with a plurality of semiconductor packages mounted on a surface of PCB 52. Electronic device 50 can have one type of semiconductor package, or multiple types of semiconductor packages, depending on the application. The different types of semiconductor packages are shown in FIG. 1 for purposes of illustration.

Electronic device 50 can be a stand-alone system that uses the semiconductor packages to perform one or more electrical functions. Alternatively, electronic device 50 can be a subcomponent of a larger system. For example, electronic device 50 can be part of a cellular phone, personal digital assistant (PDA), digital video camera (DVC), or other electronic communication device. Alternatively, electronic device 50 can be a graphics card, network interface card, or other signal processing card that can be inserted into a computer. The semiconductor package can include microprocessors, memories, application specific integrated circuits (ASIC), logic circuits, analog circuits, radio frequency (RF) circuits, discrete devices, or other semiconductor die or electrical components. Miniaturization and weight reduction are essential for the products to be accepted by the market. The distance between semiconductor devices may be decreased to achieve higher density.

In FIG. 1, PCB 52 provides a general substrate for structural support and electrical interconnect of the semiconductor packages mounted on the PCB. Conductive signal traces 54 are formed over a surface or within layers of PCB 52 using evaporation, electrolytic plating, electroless plating, screen printing, or other suitable metal deposition process. Signal traces 54 provide for electrical communication between each of the semiconductor packages, mounted components, and other external system components. Traces 54 also provide power and ground connections to each of the semiconductor packages.

In some embodiments, a semiconductor device has two packaging levels. First level packaging is a technique for mechanically and electrically attaching the semiconductor die to an intermediate carrier. Second level packaging involves mechanically and electrically attaching the intermediate carrier to the PCB. In other embodiments, a semiconductor device may only have the first level packaging where the die is mechanically and electrically mounted directly to the PCB.

For the purpose of illustration, several types of first level packaging, including bond wire package 56 and flipchip 58, are shown on PCB 52. Additionally, several types of second level packaging, including ball grid array (BGA) 60, bump chip carrier (BCC) 62, land grid array (LGA) 66, multi-chip module (MCM) 68, quad flat non-leaded package (QFN) 70, quad flat package 72, embedded wafer level ball grid array (eWLB) 74, and wafer level chip scale package (WLCSP) 76 are shown mounted on PCB 52. eWLB 74 is a fan-out wafer level package (Fo-WLP) and WLCSP 76 is a fan-in wafer level package (Fi-WLP). Depending upon the system requirements, any combination of semiconductor packages, configured with any combination of first and second level packaging styles, as well as other electronic components, can be connected to PCB 52. In some embodiments, electronic device 50 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and less expensive to manufacture resulting in a lower cost for consumers.

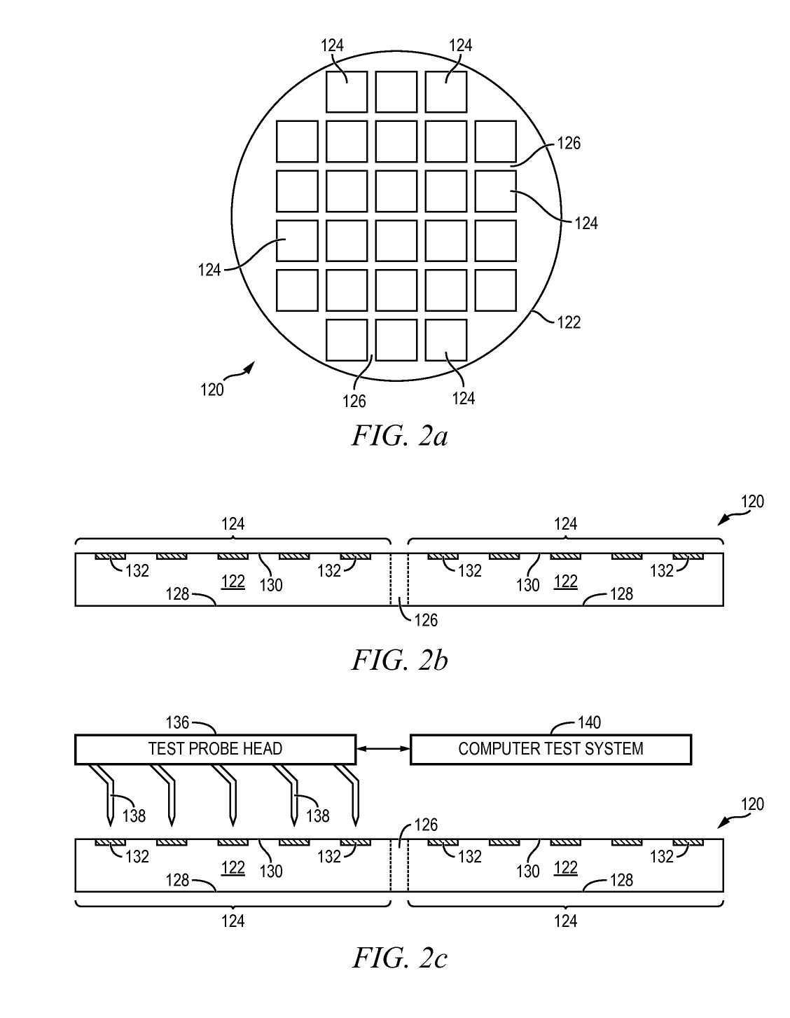

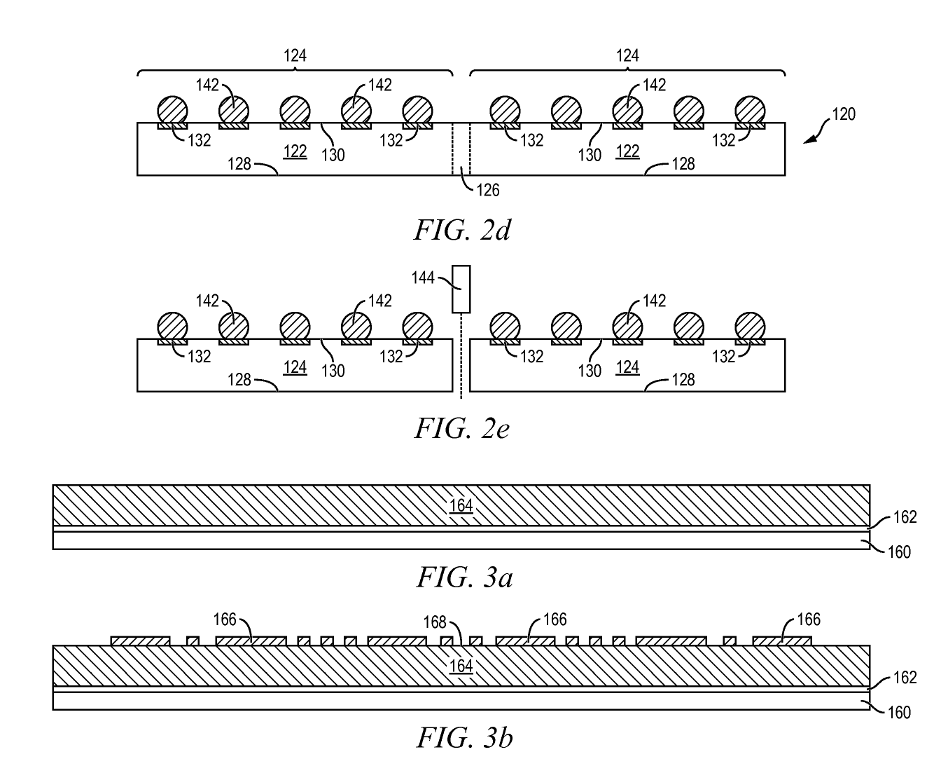

FIG. 2a shows a semiconductor wafer 120 with a base substrate material 122, such as silicon, germanium, aluminum phosphide, aluminum arsenide, gallium arsenide, gallium nitride, indium phosphide, silicon carbide, or other bulk semiconductor material for structural support. A plurality of semiconductor die or components 124 is formed on wafer 120 separated by a non-active, inter-die wafer area or saw street 126 as described above. Saw street 126 provides cutting areas to singulate semiconductor wafer 120 into individual semiconductor die 124. In one embodiment, semiconductor wafer 120 has a width or diameter of 200-300 millimeters (mm). In another embodiment, semiconductor wafer 120 has a width or diameter of 100-450 mm.

FIG. 2b shows a cross-sectional view of a portion of semiconductor wafer 120. Each semiconductor die 124 has a back or non-active surface 128 and an active surface 130 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 130 to implement analog circuits or digital circuits, such as digital signal processor (DSP), ASIC, memory, or other signal processing circuit. Semiconductor die 124 may also contain integrated passive devices (IPDs), such as inductors, capacitors, and resistors, for RF signal processing.

An electrically conductive layer 132 is formed over active surface 130 using PVD, CVD, electrolytic plating, electroless plating process, or other suitable metal deposition process. Conductive layer 132 can be one or more layers of aluminum (Al), copper (Cu), tin (Sn), nickel (Ni), gold (Au), silver (Ag), or other suitable electrically conductive material. Conductive layer 132 operates as contact pads electrically connected to the circuits on active surface 130. Conductive layer 132 can be formed as contact pads disposed side-by-side a first distance from the edge of semiconductor die 124, as shown in FIG. 2b. Alternatively, conductive layer 132 can be formed as contact pads that are offset in multiple rows such that a first row of contact pads is disposed a first distance from the edge of the die, and a second row of contact pads alternating with the first row is disposed a second distance from the edge of the die.

In FIG. 2c, semiconductor wafer 120 undergoes electrical testing and inspection as part of a quality control process. Manual visual inspection and automated optical systems are used to perform inspections on semiconductor wafer 120. Software can be used in the automated optical analysis of semiconductor wafer 120. Visual inspection methods may employ equipment such as a scanning electron microscope, high-intensity or ultra-violet light, or metallurgical microscope. Semiconductor wafer 120 is inspected for structural characteristics including warpage, thickness variation, surface particulates, irregularities, cracks, delamination, and discoloration.

The active and passive components within semiconductor die 124 undergo testing at the wafer level for electrical performance and circuit function. Each semiconductor die 124 is tested for functionality and electrical parameters, as shown in FIG. 2c, using a test probe head 136 including a plurality of probes or test leads 138 or other testing device. Probes 138 are used to make electrical contact with nodes or contact pads 132 on each semiconductor die 124 and provide electrical stimuli to the contact pads. Semiconductor die 124 responds to the electrical stimuli, which is measured by computer test system 140 and compared to an expected response to test functionality of the semiconductor die. The electrical tests may include circuit functionality, lead integrity, resistivity, continuity, reliability, junction depth, ESD, RF performance, drive current, threshold current, leakage current, and operational parameters specific to the component type. The inspection and electrical testing of semiconductor wafer 120 enables semiconductor die 124 that pass to be designated as known good die (KGD) for use in a semiconductor package.

In FIG. 2d, an electrically conductive bump material is deposited over contact pads 132 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to contact pads 132 using a suitable attachment or bonding process. In one embodiment, the bump material is reflowed by heating the material above its melting point to form balls or bumps 142. In some applications, bumps 142 are reflowed a second time to improve electrical contact to contact pads 132. Bumps 142 can also be compression bonded or thermocompression bonded to contact pads 132. Bumps 142 represent one type of interconnect structure that can be formed over contact pads 132. The interconnect structure can also use stud bump, micro bump, or other electrical interconnect.

In FIG. 2e, semiconductor wafer 120 is singulated through saw street 126 using a saw blade or laser cutting tool 144 into individual semiconductor die 124. The individual semiconductor die 124 can be inspected and electrically tested for identification of KGD post singulation.

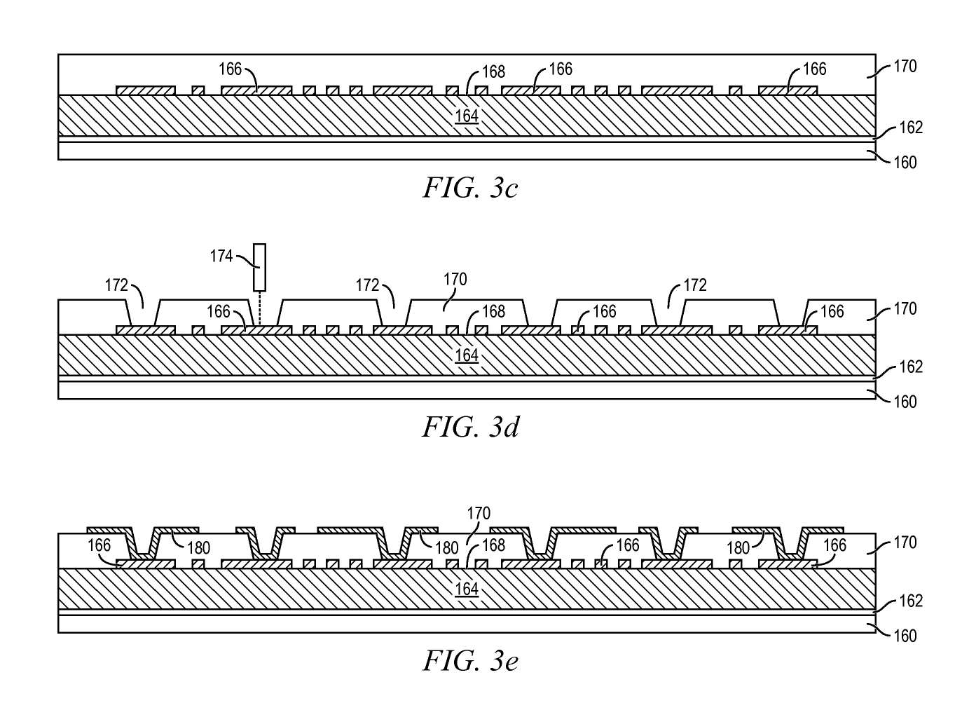

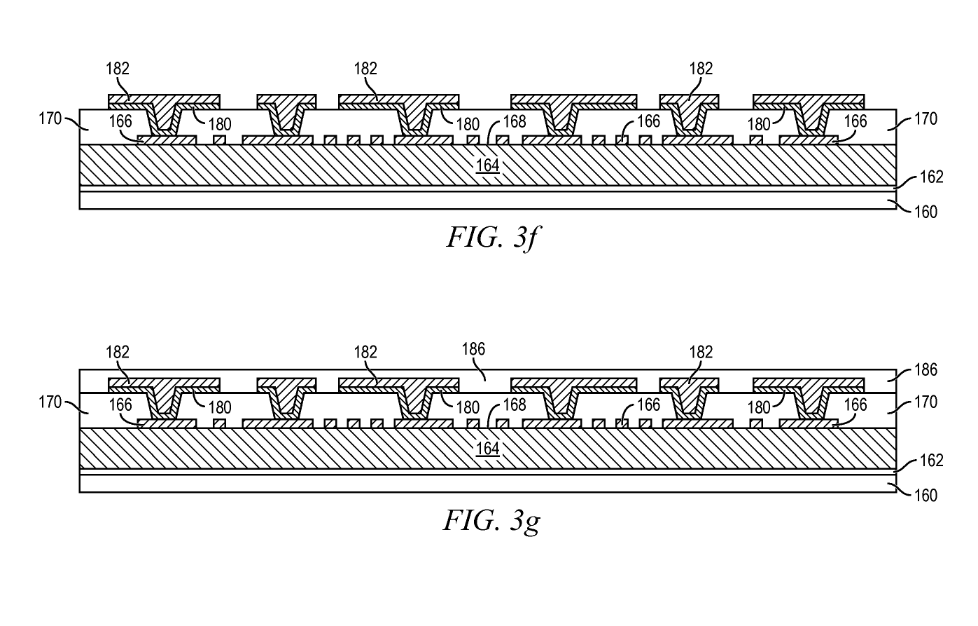

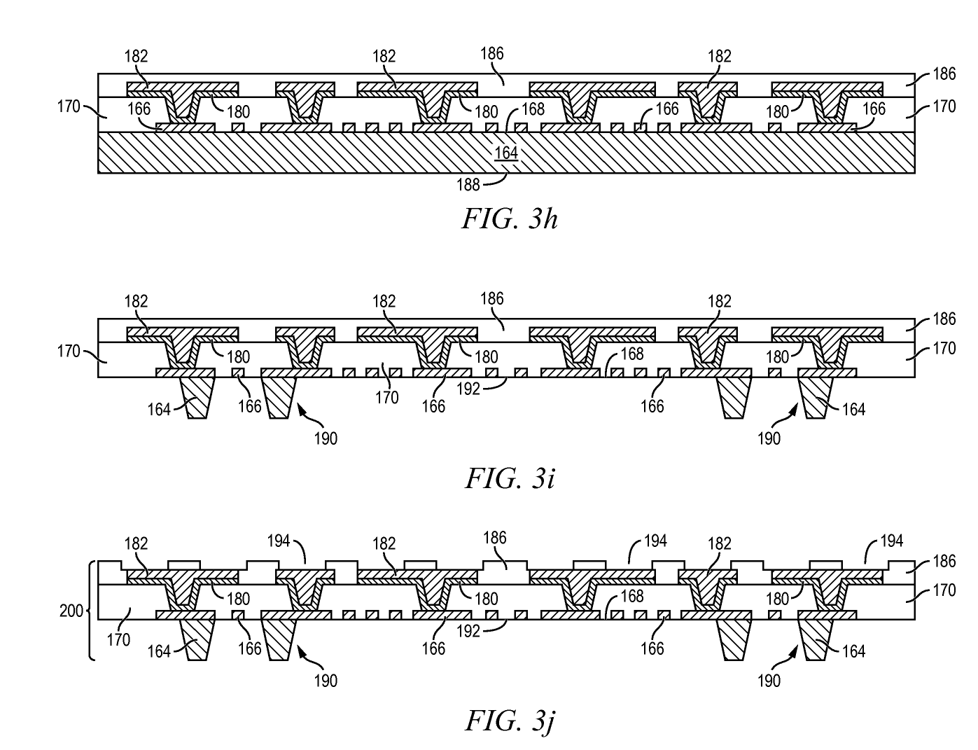

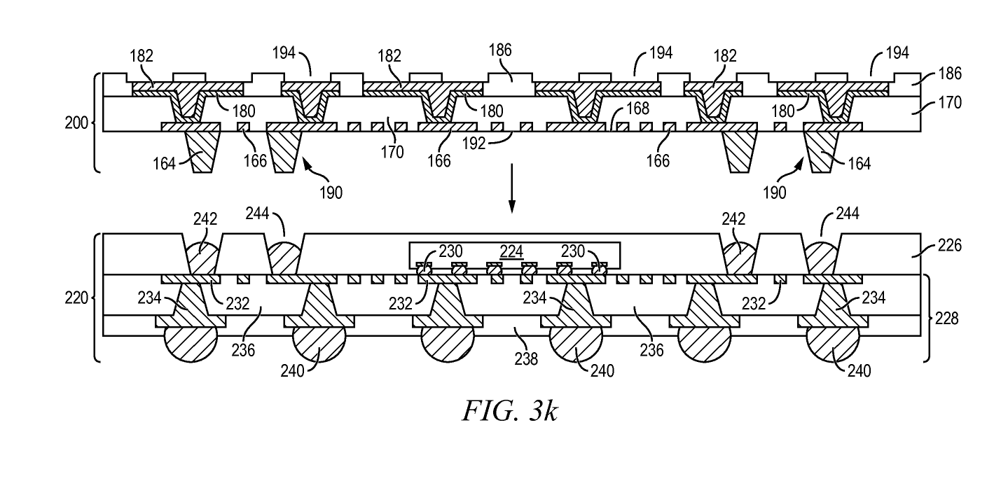

FIGS. 3a-3k illustrate, in relation to FIG. 1, a method of forming a substrate having conductive columns. FIG. 3a shows a portion of substrate or carrier 160 containing temporary or sacrificial base material such as silicon, steel, germanium, gallium arsenide, indium phosphide, silicon carbide, resin, beryllium oxide, glass, or other suitable low-cost, rigid material for structural support. Carrier 160 can be organic or inorganic base material. In one embodiment, carrier 160 includes metal. An interface layer or double-sided tape 162 is formed over carrier 160 as a temporary adhesive bonding film, etch-stop layer, or release layer.

An electrically conductive layer or metal sheet 164 is formed over carrier 160 and interface layer 162 using a metal deposition process such as Cu foil lamination, sputtering, electrolytic plating, electroless plating, or other suitable metal deposition process. Conductive layer 164 can be one or more layers of Al, Cu, Sn, Ni, Au, Ag, or other suitable electrically conductive material. In one embodiment, conductive layer 164 includes Cu or a Cu alloy.

In FIG. 3b, an electrically conductive layer 166 is formed using a metal deposition process such as PVD, CVD, sputtering, electrolytic plating, electroless plating, or other suitable metal deposition process. Conductive layer 166 can be one or more layers of Cu, Sn, Ni, Au, Ag, titanium (Ti), tungsten (W), or other suitable electrically conductive material. In one embodiment, conductive layer 166 includes plated Cu. In one embodiment, conductive layer 166 is deposited by plating Cu in patterned openings of a photoresist layer. An optional barrier layer is formed over conductive layer 164 prior to forming conductive layer 166. In one embodiment, the barrier layer is formed over conductive layer 164, and conductive layer 166 is formed over the barrier layer. The barrier layer can be Au, Ni/Au, Ni, nickel vanadium (NiV), platinum (Pt), palladium (Pd), Ni/Pd/Au, titanium tungsten (TiW), or chromium copper (CrCu).

In FIG. 3c, an insulating or dielectric layer 170 is formed over conductive layers 164 and 166 using PVD, CVD, lamination, printing, spin coating, spray coating, sintering, or thermal oxidation. Insulating layer 170 includes one or more layers of silicon dioxide (SiO2), silicon nitride (Si3N4), silicon oxynitride (SiON), tantalum pentoxide (Ta2O5), aluminum oxide (Al2O3), benzocyclobutene (BCB), polyimide (PI), polybenzoxazoles (PBO), polymer dielectric resist with or without fillers or fibers, or other material having similar structural and dielectric properties.

In FIG. 3d, a portion of insulating layer 170 is removed to form openings 172 in insulating layer 170 and expose portions of conductive layer 166. Openings 172 are formed by etching, laser direct ablation (LDA) using laser 174, or a patterning and developing process.

In FIG. 3e, an electrically conductive layer 180 is formed over insulating layer 170 within openings 172 and over conductive layer 166. Conductive layer 180 is conformally applied over insulating layer 170 and within openings 172. Conductive layer 180 is formed using a patterning and metal deposition process such as printing, PVD, CVD, lamination, sputtering, electrolytic plating, electroless plating, or other suitable metal deposition process. In one embodiment, conductive layer 180 includes a seed layer. Conductive layer 180 can be one or more layers of Ni, tantalum nitride (TaN), NiV, Pt, Pd, CrCu, or other suitable barrier or seed material.

In FIG. 3f, an electrically conductive layer 182 is formed over conductive layers 180 and 166 within openings 172 using a deposition process such as sputtering, electrolytic plating, or electroless plating. Conductive layer 182 can be one or more layers of Al, Cu, Sn, Ni, Au, Ag, Ti, W, or other suitable electrically conductive material. In one embodiment, conductive layer 182 includes plated Cu. Conductive layers 166 and 182 operate as redistribution layers (RDLs). Conductive layer 182 provides horizontal interconnection along insulating layer 170 and vertical interconnection through openings 172 in insulating layer 170. A portion of conductive layer 182 is electrically connected to conductive layer 166. Other portions of conductive layer 182 can be electrically common or electrically isolated.

In FIG. 3g, an insulating or passivation layer 186 is formed over conductive layer 182 and insulating layer 170 using PVD, CVD, printing, spin coating, spray coating, sintering or thermal oxidation. Insulating layer 186 contains one or more layers of solder resist, SiO2, Si3N4, SiON, Ta2O5, Al2O3, or other material having similar insulating and structural properties.

In FIG. 3h, carrier 160 and interface layer 162 are removed by chemical etching, mechanical peeling, chemical mechanical planarization (CMP), mechanical grinding, thermal bake, UV light, laser scanning, or wet stripping to expose conductive layer 164. After carrier 160 and interface layer 162 are removed, surface 188 of conductive layer 164 is exposed.

In FIG. 3i, a portion of conductive layer 164 is removed by an etching process to leave individual conductive columns or pillars 190. Portions of conductive layer 164 are removed to expose conductive layer 166 and insulating layer 170 at surface 192. Conductive pillars 190 are electrically connected to conductive layers 166, 180, and 182. Conductive pillars 190 can be formed with any shape and height. Conductive pillars 190 can have a cylindrical shape with a circular or oval cross-section, or conductive pillars 190 can have a cubic shape with a rectangular cross-section. In one embodiment, conductive pillars 190 include a height of 100 micrometers (μm) or greater. In another embodiment, conductive pillars 190 include a height of less than 100 μm.

In FIG. 3j, a portion of insulating layer 186 is removed by a patterning and developing process to form openings 194 and to expose portions of conductive layer 182. The exposed conductive layer 182 can be treated with an organic solderability preservative (OSP), Ni/Au, Ni/Pd/Au, Sn, or other suitable material. Conductive layers 166, 180, and 182, together with conductive pillars 190 and insulating layers 170 and 176 form a conductive column substrate 200. Conductive column substrate 200 is singulated through insulating layers 170 and 186 to form individual units of conductive column substrate 200.

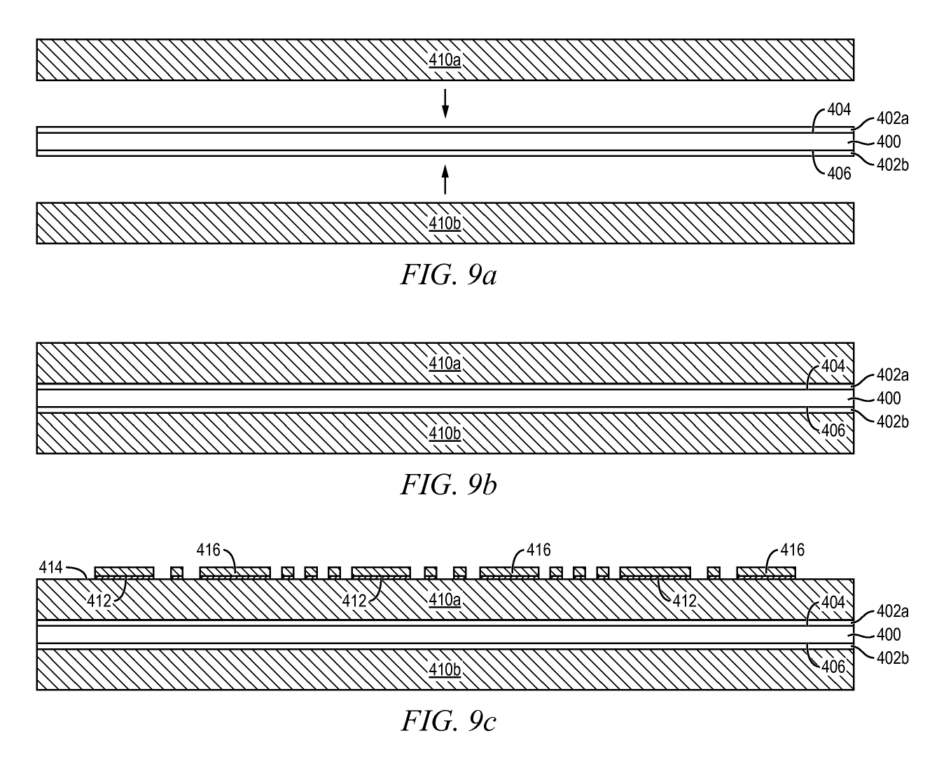

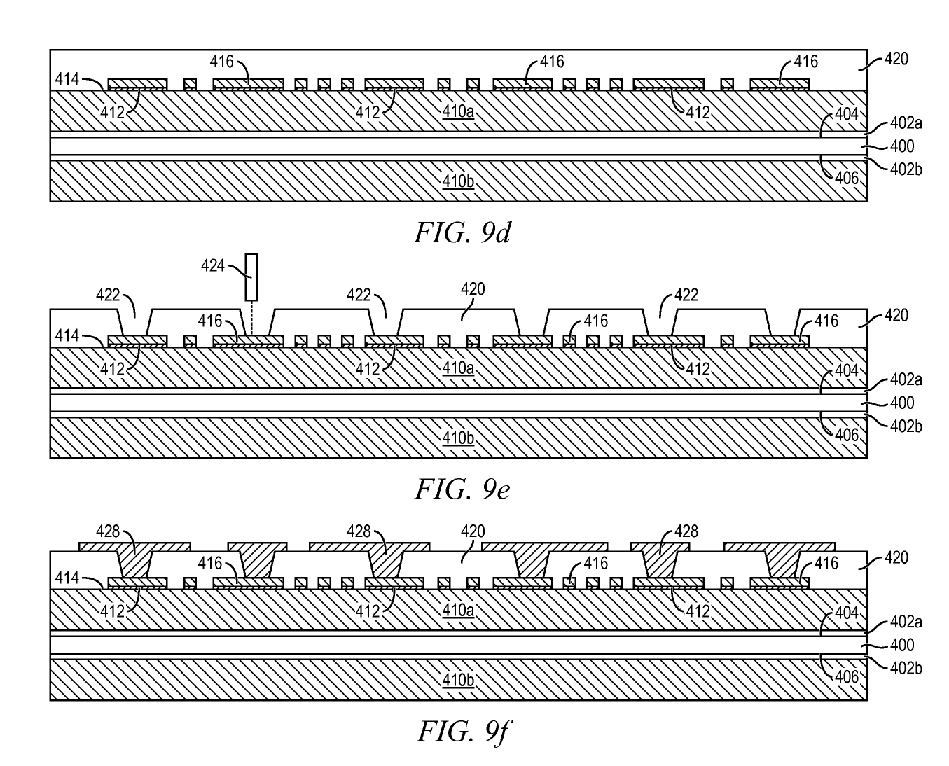

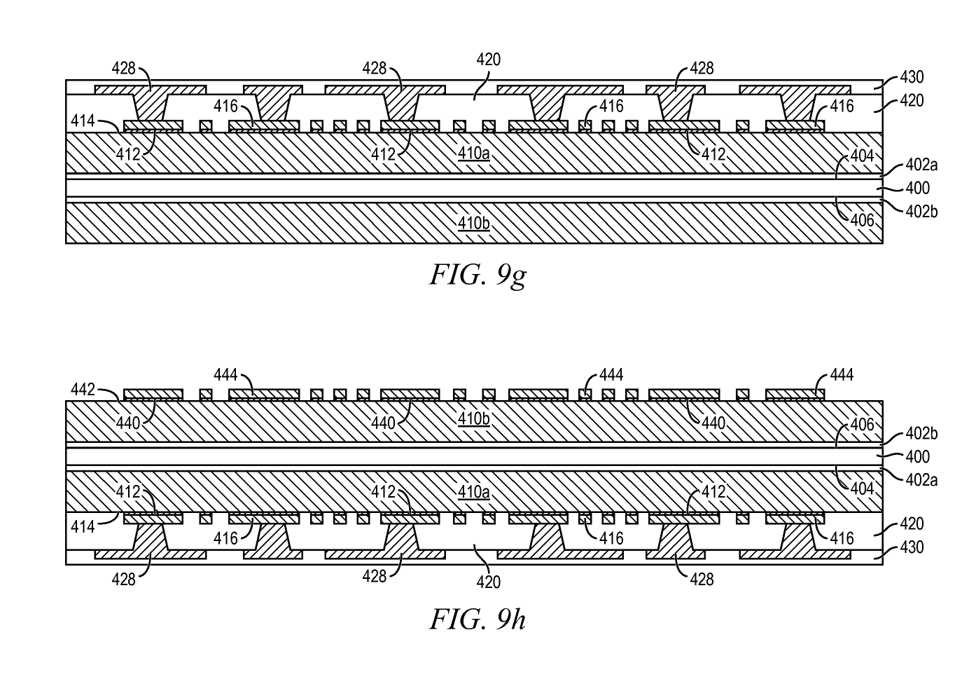

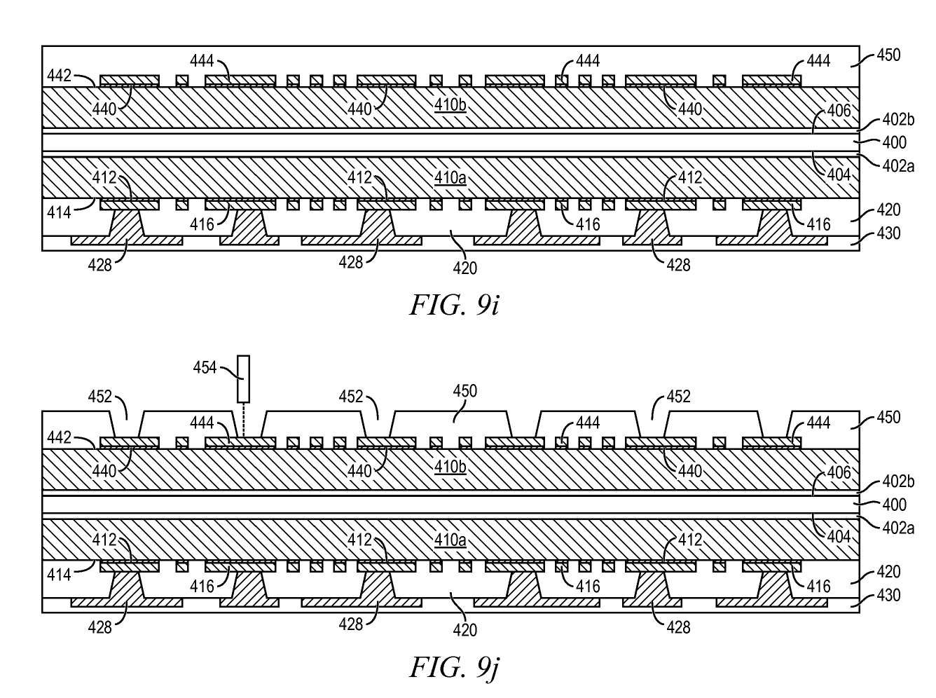

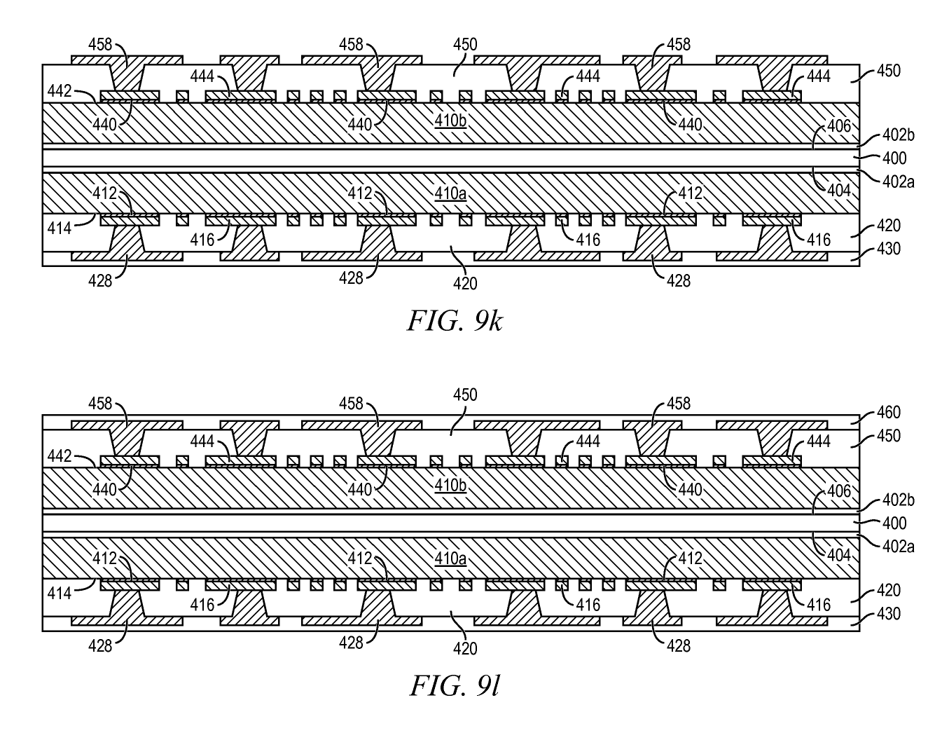

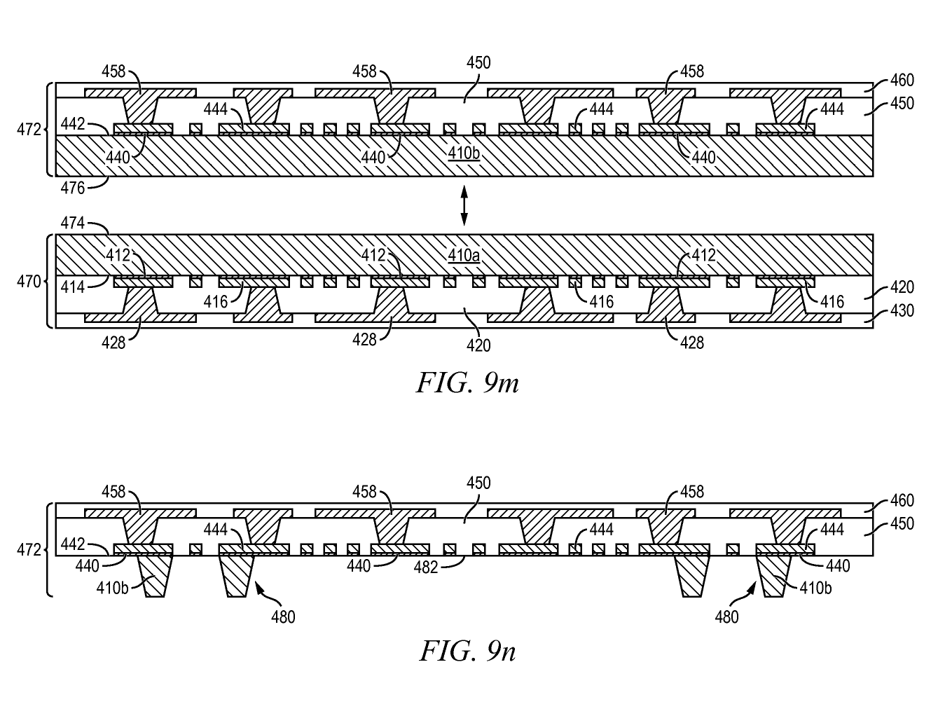

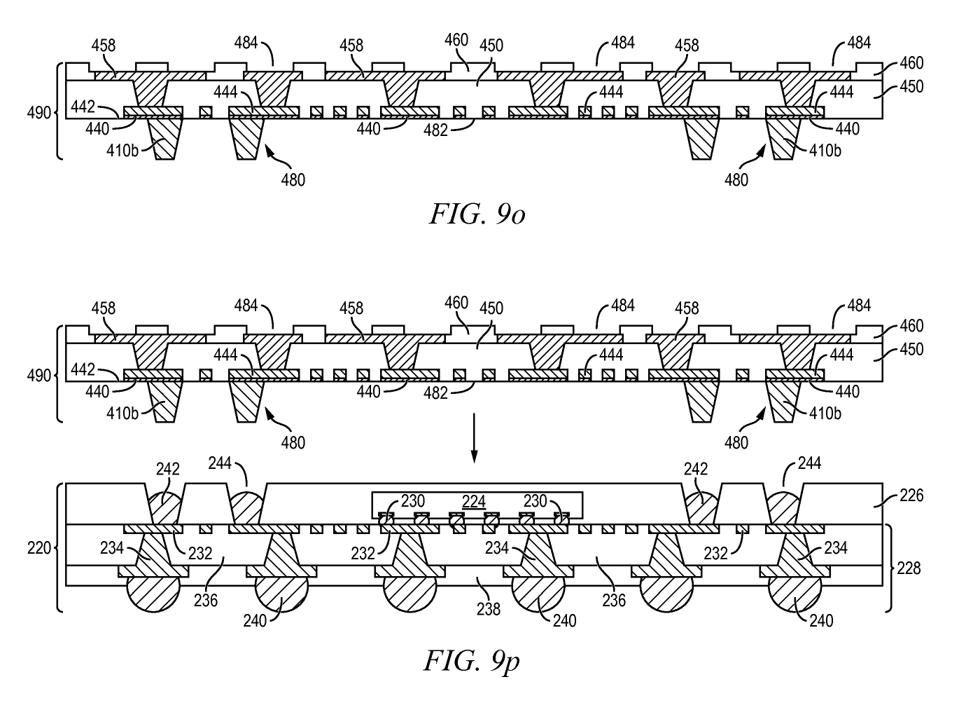

Conductive column substrate 200 contains one or more insulating or dielectric layers. Conductive column substrate 200 also contains one or more conductive layers operating as RDLs to provide electrical interconnect laterally and vertically through conductive column substrate 200. Conductive column substrate 200 provides electrical interconnect between a first surface of conductive column substrate 200 to a second surface opposite the first surface. Conductive column substrate 200 is used as an interposer for vertical or stacked semiconductor device integration. Conductive pillars 190 are electrically connected through conductive layers 166 and 180 to conductive layer 182. Conductive column substrate 200 provides interconnection for additional devices mounted over conductive layer 182 and for additional devices mounted over conductive pillars 190. Etching conductive layer 164 reduces the need for expensive plating materials in the process of forming conductive pillars 190. The process of forming conductive pillars 190 by etching conductive layer 164 reduces the cost of forming conductive pillars 190 over an interposer, such as conductive column substrate 200. Additionally, conductive pillars 190 formed by etching can have a greater height than conductive pillars formed by other processing methods, such as plating. Conductive column substrate 200 can also be formed using a double-sided process similar to the process shown in FIGS. 9a-9o.

FIG. 3k shows a process of disposing conductive column substrate 200 over a semiconductor package 220. Semiconductor package 220 comprises a bottom package-on-package (PoPb) device. In one embodiment, semiconductor package 220 includes an eWLB PoPb device including interconnections outside a footprint of semiconductor die 224. Semiconductor package 220 includes semiconductor die 224 surrounded by encapsulant 226. Interconnect structure 228 is formed over semiconductor die 224 and encapsulant 226. Semiconductor die 224 is electrically connected to interconnect structure 228 through bumps 230. In one embodiment, interconnect structure 228 includes a build-up interconnect structure including conductive layers 232 and 234, insulating layers 236 and 238, and bumps 240. Build-up interconnect structure 228 includes an electrically conductive layer or RDL 232 formed using a patterning and metal deposition process such as sputtering, electrolytic plating, and electroless plating. Conductive layer 232 can be one or more layers of Al, Cu, Sn, Ni, Au, Ag, or other suitable electrically conductive material.

Build-up interconnect structure 228 further includes an insulating or passivation layer 236 formed between conductive layer 232 for electrical isolation using PVD, CVD, printing, spin coating, spray coating, sintering or thermal oxidation. Insulating layer 236 contains one or more layers of SiO2, Si3N4, SiON, Ta2O5, Al2O3, or other material having similar insulating and structural properties. A portion of insulating layer 236 is removed by etching, LDA, or a patterning and developing process to form openings to expose conductive layer 232.

An electrically conductive layer 234 is formed over conductive layer 232 using a deposition process such as sputtering, electrolytic plating, or electroless plating. Conductive layer 234 can be one or more layers of Al, Cu, Sn, Ni, Au, Ag, or other suitable electrically conductive material. Conductive layers 232 and 234 operate as RDLs.

An insulating or passivation layer 238 is formed over insulating layer 236 and conductive layer 234 using PVD, CVD, printing, lamination, spin coating, or spray coating. Insulating layer 238 contains one or more layers of SiO2, Si3N4, SiON, Ta2O5, Al2O3, solder resist, or other material having similar insulating and structural properties. A portion of insulating layer 238 is removed by etching, LDA, or a patterning and developing process to expose conductive layer 234.

An electrically conductive bump material is deposited over build-up interconnect structure 228 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 234 using a suitable attachment or bonding process. In one embodiment, the bump material is reflowed by heating the material above its melting point to form balls or bumps 240. In some applications, bumps 240 are reflowed a second time to improve electrical contact to conductive layer 234. An under bump metallization (UBM) layer can be formed under bumps 240. Bumps 240 can also be compression bonded to conductive layer 234. Bumps 240 represent one type of interconnect structure that can be formed over conductive layer 234. The interconnect structure can also use bond wires, stud bump, micro bump, or other electrical interconnect.

Semiconductor package 220 includes recessed vertical interconnects or bumps 242 to accommodate stacked semiconductor devices in a PoP arrangement. Openings 244 are formed through a surface of encapsulant 226 opposite interconnect structure 228. Bumps 242 are recessed within openings 244 in encapsulant 226. Openings 244 accommodate conductive pillars 190.

Conductive column substrate 200 is mounted over semiconductor package 220 with conductive pillars 190 oriented toward semiconductor package 220. Conductive pillars 190 align with openings 244 and are disposed within openings 244 to electrically connect to bumps 242. Semiconductor die 224 is electrically connected to conductive column substrate 200 through bumps 230, interconnect structure 228, bumps 242, and conductive pillars 190. Conductive column substrate 200 provides electrical interconnection to external devices through conductive pillars 190, bumps 242, interconnect structure 228, and bumps 240. Conductive pillars 190 provide a vertical interconnect with a height that extends into openings of a PoPb package for stacked PoP configurations. Conductive pillars 190 of conductive column substrate 200 disposed within openings 244 reduces the height of the overall semiconductor package.

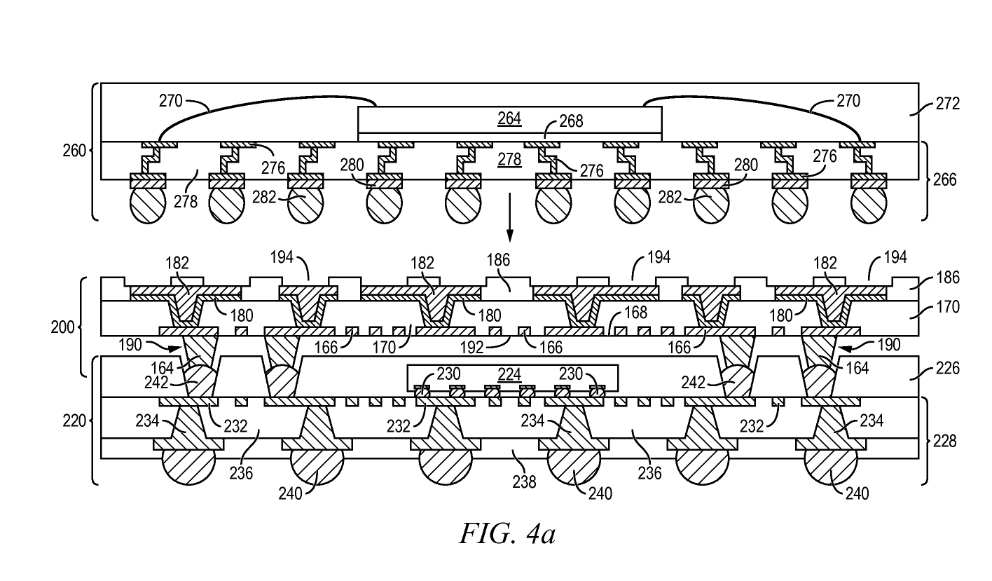

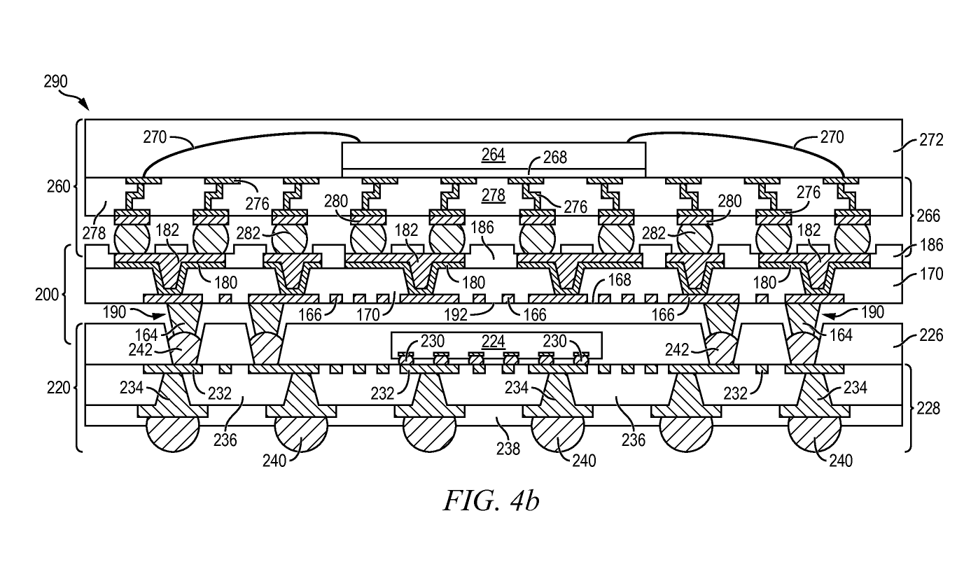

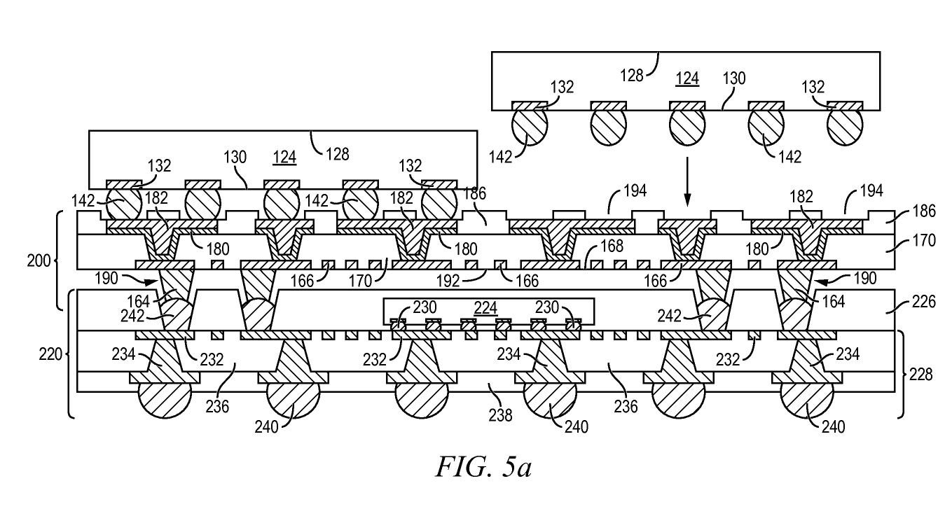

FIGS. 4a-4b illustrate, in relation to FIGS. 1 and 3a-3k, a method of forming a semiconductor device including a conductive column substrate. Continuing from FIG. 3k, FIG. 4a shows a process of disposing semiconductor package 260 over conductive column substrate 200. Semiconductor package 260 comprises a top package-on-package (PoPt) device. Semiconductor die 264 is mounted to substrate or interposer 266 using die attach adhesive 268, such as epoxy resin. Bond wires 270 are formed between interposer 266 and contact pads on an active surface of semiconductor die 264. An encapsulant 272 is deposited over semiconductor die 264, substrate 266, and bond wires 270. Interposer 266 includes one or more conductive layers 276 and one or more insulating or passivation layers 278. Conductive layers 276 provide vertical and horizontal conduction paths through interposer 266. Portions of conductive layers 276 are electrically common or electrically isolated according to the design and function of the semiconductor die to be mounted to interposer 266.

An electrically conductive layer 280 is formed over conductive layer 276 using a deposition process such as sputtering, electrolytic plating, or electroless plating. Conductive layer 280 can be Al, Cu, Sn, Ni, Au, Ag, or other suitable electrically conductive material. Conductive layer 280 is a UBM electrically connected to conductive layer 276. UBMs 280 can be a multi-metal stack with adhesion layer, barrier layer, and seed or wetting layer. The adhesion layer is formed over conductive layer 276 and can be Ti, TiN, TiW, Al, or Cr. The barrier layer is formed over the adhesion layer and can be Au, Ni/Au, Ni, NiV, Pt, Pd, Ni/Pd/Au, TiW, or CrCu. The barrier layer inhibits the diffusion of Cu into the active area of the die. The seed layer is formed over the barrier layer and can be Cu, Ni, TaN, NiV, Au, CrCu, or Al. UBMs 280 provide a low resistive interconnect to conductive layer 276, as well as a barrier to solder diffusion and seed layer for solder wettability.

An electrically conductive bump material is deposited over a surface of interposer 266 opposite semiconductor die 264 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 280 using a suitable attachment or bonding process. In one embodiment, the bump material is reflowed by heating the material above its melting point to form balls or bumps 282. In some applications, bumps 282 are reflowed a second time to improve electrical contact to conductive layer 280. Bumps 282 can also be compression bonded to conductive layer 280. Bumps 282 represent one type of interconnect structure that can be formed over interposer 266. The interconnect structure can also use bond wires, stud bump, micro bump, or other electrical interconnect.

Semiconductor package 260 is disposed over conductive column substrate 200 with bumps 282 oriented toward conductive column substrate 200.

FIG. 4b shows semiconductor package 260 disposed over conductive column substrate 200 to form semiconductor device 290. Semiconductor device 290 comprises a package-on-package interposer device including conductive column substrate 200 disposed between semiconductor package 260 and semiconductor package 220. Semiconductor package 260 is mounted to conductive column substrate 200 with bumps 282 metallurgically and electrically connected to conductive layer 182. Conductive column substrate 200 provides electrical interconnect for semiconductor package 260 to semiconductor package 220 and to external devices. Semiconductor die 264 is electrically connected to external devices through wire bonds 270, interposer 266, UBM 280, bumps 282, conductive column substrate 200, and semiconductor package 220.

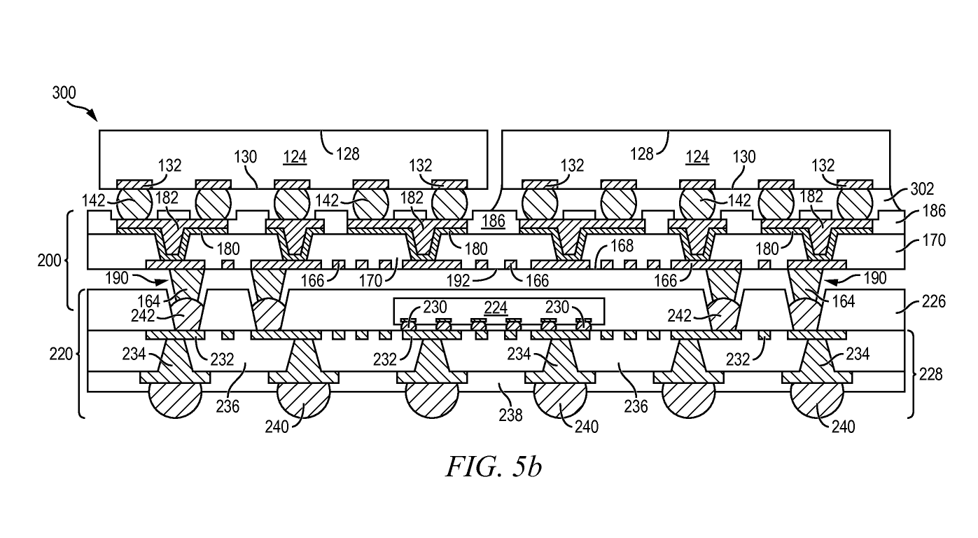

FIGS. 5a-5b illustrate, in relation to FIGS. 1, 2a-2e, and 3a-3k, another method of forming a semiconductor package including a conductive column substrate. Continuing from FIG. 3k, FIG. 5a shows a process of disposing semiconductor die 124 from FIG. 2e over conductive column substrate 200. Semiconductor die 124 are mounted to conductive column substrate 200 with bumps 142 oriented toward conductive column substrate 200.

FIG. 5b shows semiconductor die 124 mounted to conductive column substrate 200 with bumps 142 electrically connected to conductive layer 182 to form semiconductor device 300. An optional underfill material 302, such as epoxy resin, disposed under semiconductor die 124 and around bumps 142. Semiconductor device 300 comprises a package-on-package interposer device including conductive column substrate 200 disposed between semiconductor die 124 and semiconductor package 220. Semiconductor die 124 are mounted to conductive column substrate 200 with bumps 142 metallurgically and electrically connected to conductive layer 182. Conductive column substrate 200 provides electrical interconnect for semiconductor die 124 to semiconductor package 220 and to external devices. Semiconductor die 124 is electrically connected to external devices through bumps 142, conductive column substrate 200, and semiconductor package 220.

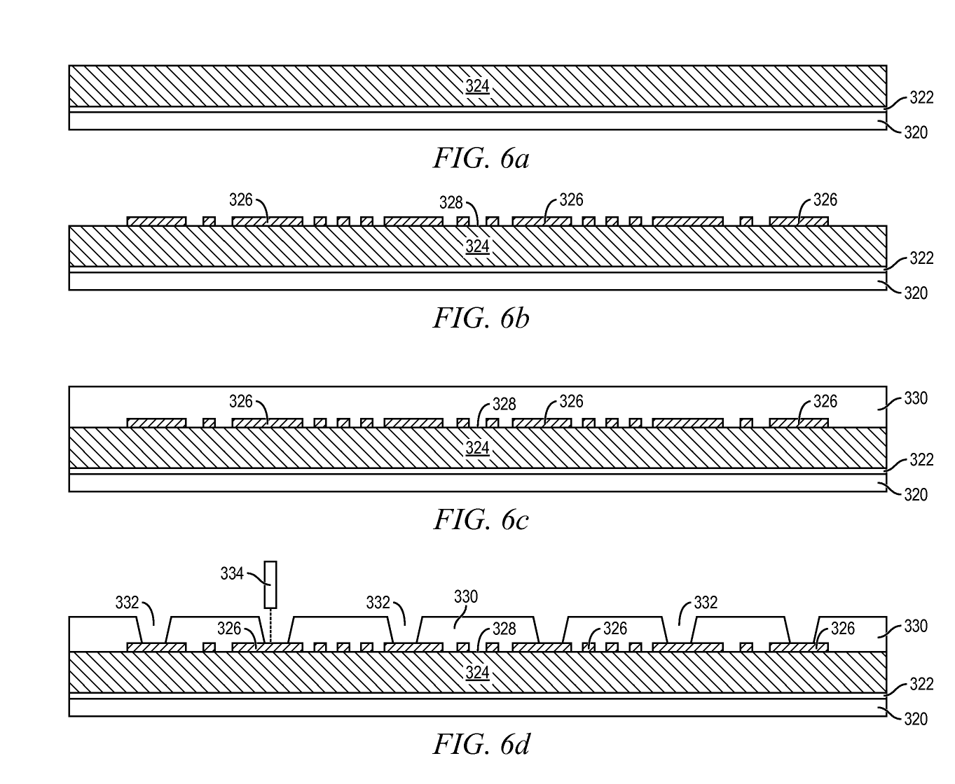

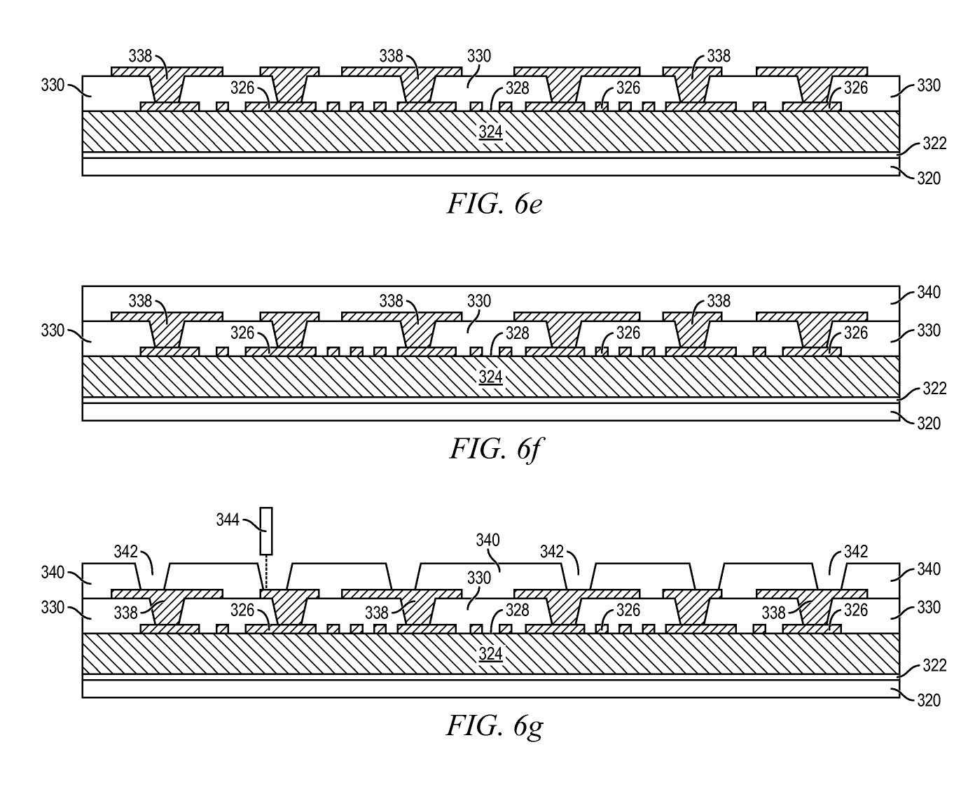

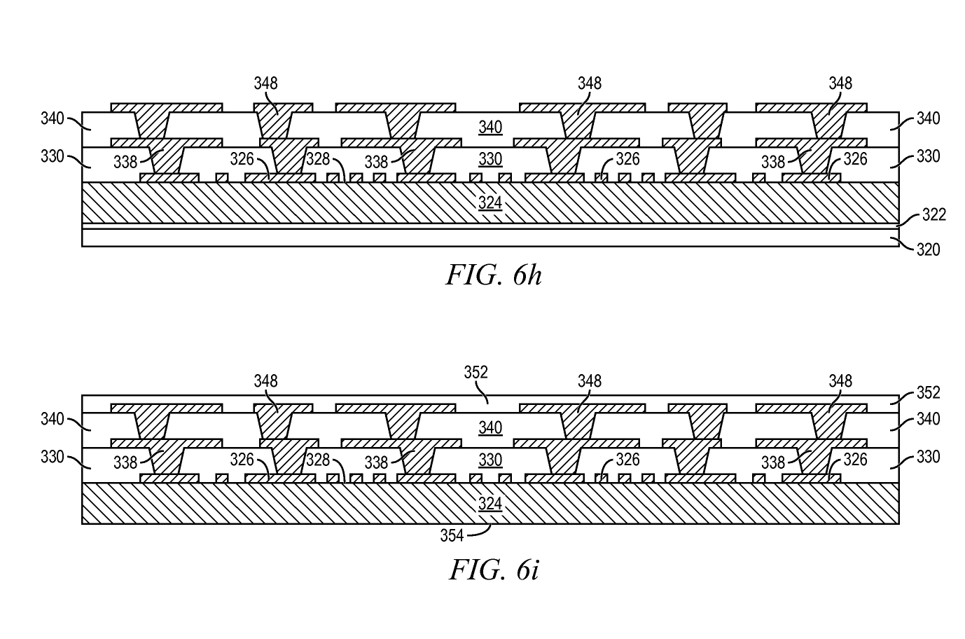

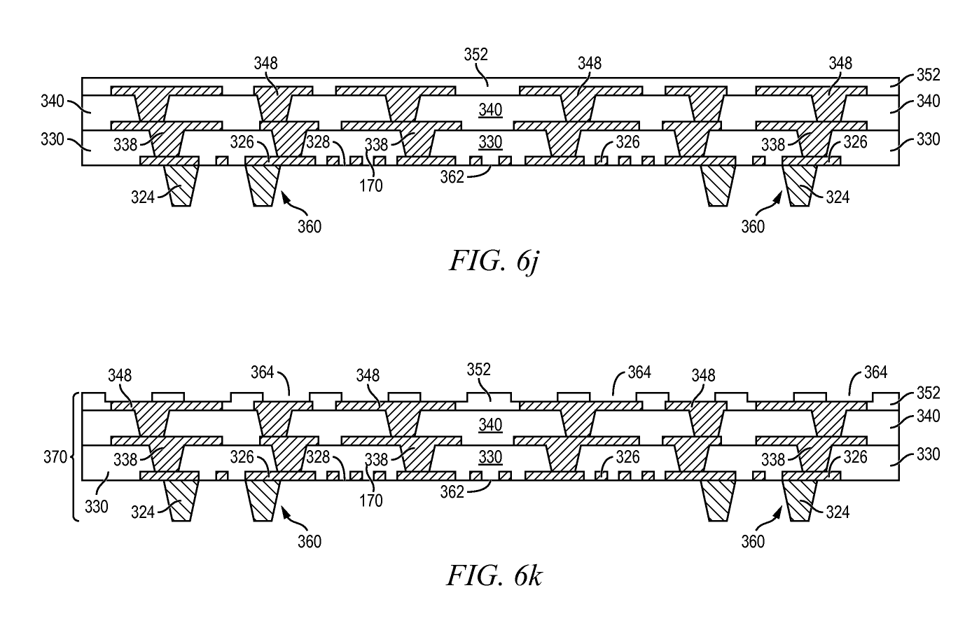

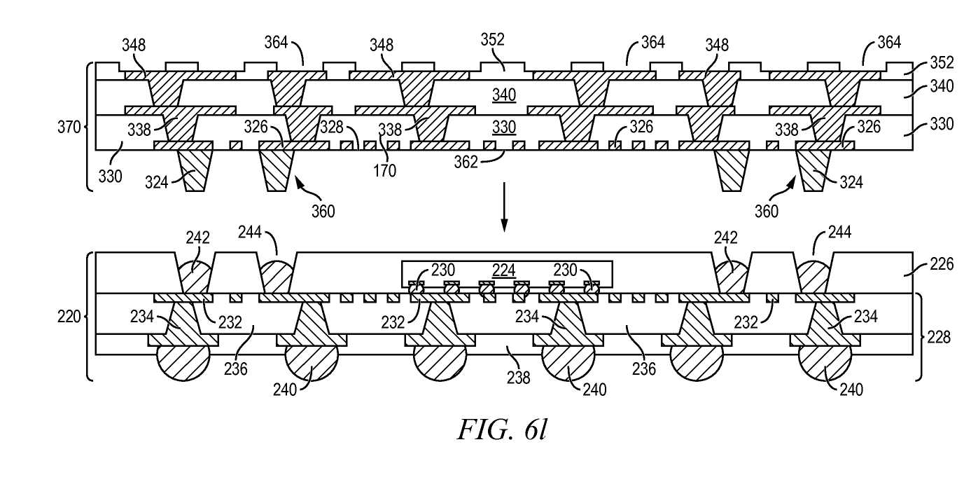

FIGS. 6a-6l illustrate, in relation to FIG. 1, another method of forming a substrate having conductive columns. FIG. 6a shows a portion of substrate or carrier 320 containing temporary or sacrificial base material such as silicon, steel, germanium, gallium arsenide, indium phosphide, silicon carbide, resin, beryllium oxide, glass, or other suitable low-cost, rigid material for structural support. Carrier 320 can be organic or inorganic base material. In one embodiment, carrier 320 includes metal. An interface layer or double-sided tape 322 is formed over carrier 320 as a temporary adhesive bonding film, etch-stop layer, or release layer.

An electrically conductive layer or metal sheet 324 is formed over carrier 320 and interface layer 322 using a metal deposition process such as Cu foil lamination, sputtering, electrolytic plating, electroless plating, or other suitable metal deposition process. Conductive layer 324 can be one or more layers of Al, Cu, Sn, Ni, Au, Ag, or other suitable electrically conductive material. In one embodiment, conductive layer 324 includes Cu or a Cu alloy.

In FIG. 6b, an electrically conductive layer 326 is formed using a metal deposition process such as PVD, CVD, sputtering, electrolytic plating, electroless plating, or other suitable metal deposition process. Conductive layer 326 can be one or more layers of Cu, Sn, Ni, Au, Ag, Ti, W, or other suitable electrically conductive material. In one embodiment, conductive layer 326 includes plated Cu. In one embodiment, conductive layer 326 is deposited by plating Cu in patterned openings of a photoresist layer. An optional barrier layer is formed over conductive layer 324 prior to forming conductive layer 326. In one embodiment, the barrier layer is formed over conductive layer 324, and conductive layer 326 is formed over the barrier layer. The barrier layer can be Au, Ni/Au, Ni, NiV, Pt, Pd, Ni/Pd/Au, TiW, or CrCu.

In FIG. 6c, an insulating or dielectric layer 330 is formed over conductive layers 324 and 326 using PVD, CVD, lamination, printing, spin coating, spray coating, sintering, or thermal oxidation. Insulating layer 330 includes one or more layers of SiO2, Si3N4, SiON, Ta2O5, Al2O3, BCB, PI, PBO, polymer dielectric resist with or without fillers or fibers, or other material having similar structural and dielectric properties.

In FIG. 6d, a portion of insulating layer 330 is removed to form openings 332 in insulating layer 330 and expose portions of conductive layer 326. Openings 332 are formed by etching, LDA using laser 334, or a patterning and developing process.

In FIG. 6e, an electrically conductive layer 338 is formed over insulating layer 330 within openings 332 and over conductive layer 326. Conductive layer 338 is formed using a patterning and metal deposition process such as printing, PVD, CVD, lamination, sputtering, electrolytic plating, electroless plating, or other suitable metal deposition process. Conductive layer 338 can be one or more layers of Al, Cu, Sn, Ni, Au, Ag, or other suitable electrically conductive material. In one embodiment, conductive layer 338 includes plated Cu. An optional seed layer is formed over insulating layer 330 within openings 332 prior to forming conductive layer 338. In one embodiment, conductive layer 338 is formed over the seed layer. The seed layer can be Ni, TaN, NiV, Pt, Pd, CrCu, or other suitable barrier or seed material. Conductive layer 338 operates as an RDL to provide horizontal interconnection along insulating layer 330 and vertical interconnection through openings 332 in insulating layer 330. A portion of conductive layer 338 is electrically connected to conductive layers 326 and 324. Other portions of conductive layer 338 can be electrically common or electrically isolated.

In FIG. 6f, an insulating or dielectric layer 340 is formed over conductive layer 338 and insulating layer 330 using PVD, CVD, lamination, printing, spin coating, spray coating, sintering, or thermal oxidation. Insulating layer 340 includes one or more layers of SiO2, Si3N4, SiON, Ta2O5, Al2O3, BCB, PI, PBO, polymer dielectric resist with or without fillers or fibers, or other material having similar structural and dielectric properties.

In FIG. 6g, a portion of insulating layer 340 is removed to form openings 342 in insulating layer 340 and expose portions of conductive layer 338. Openings 342 are formed by etching, LDA using laser 344, or a patterning and developing process.

In FIG. 6h, an electrically conductive layer 348 is formed over insulating layer 340 within openings 342 and over conductive layer 338. Conductive layer 348 is formed using a patterning and metal deposition process such as printing, PVD, CVD, lamination, sputtering, electrolytic plating, electroless plating, or other suitable metal deposition process. Conductive layer 348 can be one or more layers of Al, Cu, Sn, Ni, Au, Ag, or other suitable electrically conductive material. In one embodiment, conductive layer 348 includes plated Cu. An optional seed layer is formed over insulating layer 340 within openings 342 prior to forming conductive layer 348. In one embodiment, conductive layer 348 is formed over the seed layer. The seed layer can be Ni, TaN, NiV, Pt, Pd, CrCu, or other suitable barrier or seed material. Conductive layer 348 operates as an RDL to provide horizontal interconnection along insulating layer 340 and vertical interconnection through openings 342 in insulating layer 340. A portion of conductive layer 348 is electrically connected to conductive layers 338, 326, and 324. Other portions of conductive layer 348 can be electrically common or electrically isolated.

In FIG. 6i, an insulating or passivation layer 352 is formed over conductive layer 348 and insulating layer 340 using PVD, CVD, printing, spin coating, spray coating, sintering or thermal oxidation. Insulating layer 352 contains one or more layers of solder resist, SiO2, Si3N4, SiON, Ta2O5, Al2O3, or other material having similar insulating and structural properties.

Carrier 320 and interface layer 322 are removed by chemical etching, mechanical peeling, CMP, mechanical grinding, thermal bake, UV light, laser scanning, or wet stripping to expose conductive layer 324. After carrier 320 and interface layer 322 are removed, surface 354 of conductive layer 324 is exposed.

In FIG. 6j, a portion of conductive layer 324 is removed by an etching process to leave individual conductive columns or pillars 360. Portions of conductive layer 324 are removed to expose conductive layer 326 and insulating layer 330 at surface 362. Conductive pillars 360 are electrically connected to conductive layers 326, 338, and 348. Conductive pillars 360 can be formed with any shape and height. Conductive pillars 360 can have a cylindrical shape with a circular or oval cross-section, or conductive pillars 360 can have a cubic shape with a rectangular cross-section. In one embodiment, conductive pillars 360 include a height of 100 μm or greater. In another embodiment, conductive pillars 360 include a height of less than 100 μm.

In FIG. 6k, a portion of insulating layer 352 is removed by a patterning and developing process to form openings 364 and to expose portions of conductive layer 348. The exposed conductive layer 348 can be treated with OSP, Ni/Au, Ni/Pd/Au, Sn, or other suitable material. Conductive layers 326, 338, and 348, together with conductive pillars 360 and insulating layers 330, 340, and 352 form a conductive column substrate 370. Conductive column substrate 370 is singulated through insulating layers 330, 340, and 352 to form individual units of conductive column substrate 370. Conductive column substrate 370 comprises a multi-layer interposer. Conductive column substrate 370 can have fewer insulating layers and conductive layers or more insulating layers and conductive layers as needed for electrical interconnection.

Conductive column substrate 370 contains one or more insulating or dielectric layers. Conductive column substrate 370 also contains one or more conductive layers operating as RDLs to provide electrical interconnect laterally and vertically through conductive column substrate 370. Conductive column substrate 370 provides electrical interconnect between a first surface of conductive column substrate 370 to a second surface opposite the first surface. Conductive column substrate 370 is used as an interposer for vertical or stacked semiconductor device integration. Conductive pillars 360 are electrically connected through conductive layers 326 and 338 to conductive layer 348. Conductive column substrate 370 provides interconnection for additional devices mounted over conductive layer 348 and for additional devices mounted over conductive pillars 360. Etching conductive layer 324 reduces the need for expensive plating materials in the process of forming conductive pillars 360. The process of forming conductive pillars 360 by etching conductive layer 324 reduces the cost of forming conductive pillars 360 over an interposer, such as conductive column substrate 370. Additionally, conductive pillars 360 formed by etching can have a greater height than conductive pillars formed by other processing methods, such as plating. Conductive column substrate 370 can also be formed using a double-sided process similar to the process shown in FIGS. 9a-9o.

FIG. 6l shows a process of disposing conductive column substrate 370 over a semiconductor package 220. Semiconductor package 220 comprises a PoPb device. In one embodiment, semiconductor package 220 includes an eWLB PoPb device including interconnections outside a footprint of semiconductor die 224. Semiconductor package 220 includes semiconductor die 224 surrounded by encapsulant 226. Interconnect structure 228 is formed over semiconductor die 224 and encapsulant 226. Semiconductor die 224 is electrically connected to interconnect structure 228 through bumps 230. In one embodiment, interconnect structure 228 includes a build-up interconnect structure including conductive layers 232 and 234, insulating layers 236 and 238, and bumps 240. Build-up interconnect structure 228 includes an electrically conductive layer or RDL 232 formed using a patterning and metal deposition process such as sputtering, electrolytic plating, and electroless plating. Conductive layer 232 can be one or more layers of Al, Cu, Sn, Ni, Au, Ag, or other suitable electrically conductive material.

Build-up interconnect structure 228 further includes an insulating or passivation layer 236 formed between conductive layer 232 for electrical isolation using PVD, CVD, printing, spin coating, spray coating, sintering or thermal oxidation. Insulating layer 236 contains one or more layers of SiO2, Si3N4, SiON, Ta2O5, Al2O3, or other material having similar insulating and structural properties. A portion of insulating layer 236 is removed by etching, LDA, or a patterning and developing process to form openings to expose conductive layer 232.

An electrically conductive layer 234 is formed over conductive layer 232 using a deposition process such as sputtering, electrolytic plating, or electroless plating. Conductive layer 234 can be one or more layers of Al, Cu, Sn, Ni, Au, Ag, or other suitable electrically conductive material. Conductive layers 232 and 234 operate as RDLs.

An insulating or passivation layer 238 is formed over insulating layer 236 and conductive layer 234 using PVD, CVD, printing, lamination, spin coating, or spray coating. Insulating layer 238 contains one or more layers of SiO2, Si3N4, SiON, Ta2O5, Al2O3, solder resist, or other material having similar insulating and structural properties. A portion of insulating layer 238 is removed by etching, LDA, or a patterning and developing process to expose conductive layer 234.

An electrically conductive bump material is deposited over build-up interconnect structure 228 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 234 using a suitable attachment or bonding process. In one embodiment, the bump material is reflowed by heating the material above its melting point to form balls or bumps 240. In some applications, bumps 240 are reflowed a second time to improve electrical contact to conductive layer 234. A UBM layer can be formed under bumps 240. Bumps 240 can also be compression bonded to conductive layer 234. Bumps 240 represent one type of interconnect structure that can be formed over conductive layer 234. The interconnect structure can also use bond wires, stud bump, micro bump, or other electrical interconnect.

Semiconductor package 220 includes recessed vertical interconnects or bumps 242 to accommodate stacked semiconductor devices in a PoP arrangement. Openings 244 are formed through a surface of encapsulant 226 opposite interconnect structure 228 Bumps 242 are recessed within openings 244 of encapsulant 226. Openings 244 accommodate conductive pillars 360.

Conductive column substrate 370 is mounted over semiconductor package 220 with conductive pillars 360 oriented toward semiconductor package 220. Conductive pillars 360 align with openings 244 and are disposed within openings 244 to electrically connect to bumps 242. Semiconductor die 224 is electrically connected to conductive column substrate 370 through bumps 230, interconnect structure 228, bumps 242, and conductive pillars 360. Conductive column substrate 370 provides electrical interconnection to external devices through conductive pillars 360, bumps 242, interconnect structure 228, and bumps 240. Conductive pillars 360 provide a vertical interconnect with a height that extends to into openings of a PoPb package for stacked PoP configurations. Conductive pillars 360 of conductive column substrate 370 disposed within openings 244 reduces the height of the overall semiconductor package.

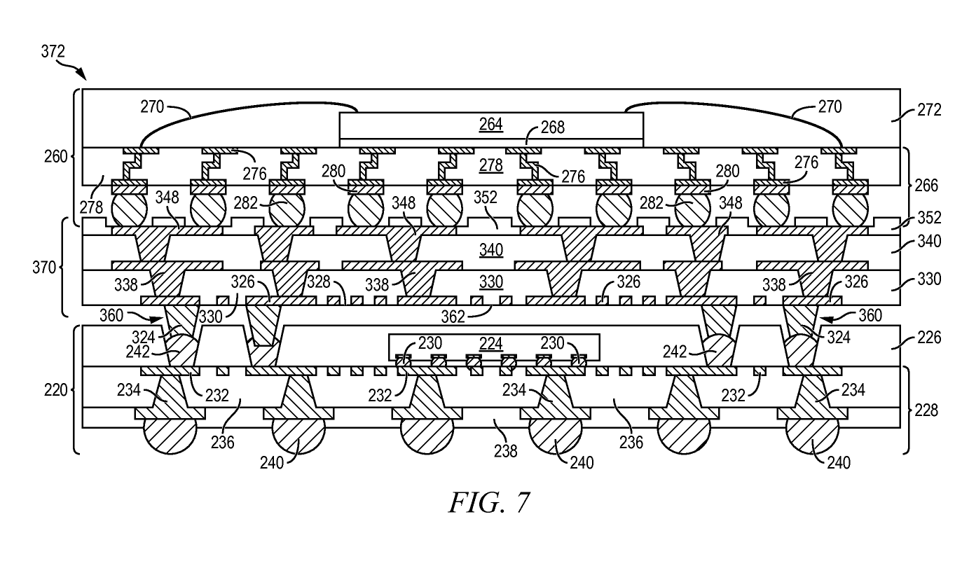

FIG. 7 illustrates, in relation to FIGS. 1 and 6a-6l, a semiconductor package including a conductive column substrate. Continuing from FIG. 6l, FIG. 7 shows semiconductor package 260 disposed over conductive column substrate 370. Semiconductor package 260 comprises a PoPt device. Semiconductor die 264 is mounted to substrate or interposer 266 using die attach adhesive 268, such as epoxy resin. Bond wires 270 are formed between interposer 266 and contact pads on an active surface of semiconductor die 264. An encapsulant 272 is deposited over semiconductor die 264, substrate 266, and bond wires 270. Interposer 266 includes one or more conductive layers 276 and one or more insulating or passivation layers 278. Conductive layers 276 provide vertical and horizontal conduction paths through interposer 266. Portions of conductive layers 276 are electrically common or electrically isolated according to the design and function of the semiconductor die to be mounted to interposer 266.

An electrically conductive layer 280 is formed over conductive layer 276 using a deposition process such as sputtering, electrolytic plating, or electroless plating. Conductive layer 280 can be Al, Cu, Sn, Ni, Au, Ag, or other suitable electrically conductive material. Conductive layer 280 is a UBM electrically connected to conductive layer 276. UBMs 280 can be a multi-metal stack with adhesion layer, barrier layer, and seed or wetting layer. The adhesion layer is formed over conductive layer 276 and can be Ti, TiN, TiW, Al, or Cr. The barrier layer is formed over the adhesion layer and can be Au, Ni/Au, Ni, NiV, Pt, Pd, Ni/Pd/Au, TiW, or CrCu. The barrier layer inhibits the diffusion of Cu into the active area of the die. The seed layer is formed over the barrier layer and can be Cu, Ni, TaN, NiV, Au, CrCu, or Al. UBMs 280 provide a low resistive interconnect to conductive layer 276, as well as a barrier to solder diffusion and seed layer for solder wettability.

An electrically conductive bump material is deposited over a surface of interposer 266 opposite semiconductor die 264 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 280 using a suitable attachment or bonding process. In one embodiment, the bump material is reflowed by heating the material above its melting point to form balls or bumps 282. In some applications, bumps 282 are reflowed a second time to improve electrical contact to conductive layer 280. Bumps 282 can also be compression bonded to conductive layer 280. Bumps 282 represent one type of interconnect structure that can be formed over interposer 266. The interconnect structure can also use bond wires, stud bump, micro bump, or other electrical interconnect.

Semiconductor package 260 is disposed over conductive column substrate 370 with bumps 282 oriented toward conductive column substrate 370. Semiconductor package 260 is mounted over conductive column substrate 370 to form semiconductor device 372. Semiconductor device 372 comprises a package-on-package interposer device including conductive column substrate 370 disposed between semiconductor package 260 and semiconductor package 220. Semiconductor package 260 is mounted to conductive column substrate 370 with bumps 282 metallurgically and electrically connected to conductive layer 348. Conductive column substrate 370 provides electrical interconnect for semiconductor package 260 to semiconductor package 220 and to external devices. Semiconductor die 264 is electrically connected to external devices through wire bonds 270, interposer 266, UBM 280, bumps 282, conductive column substrate 370, and semiconductor package 220.

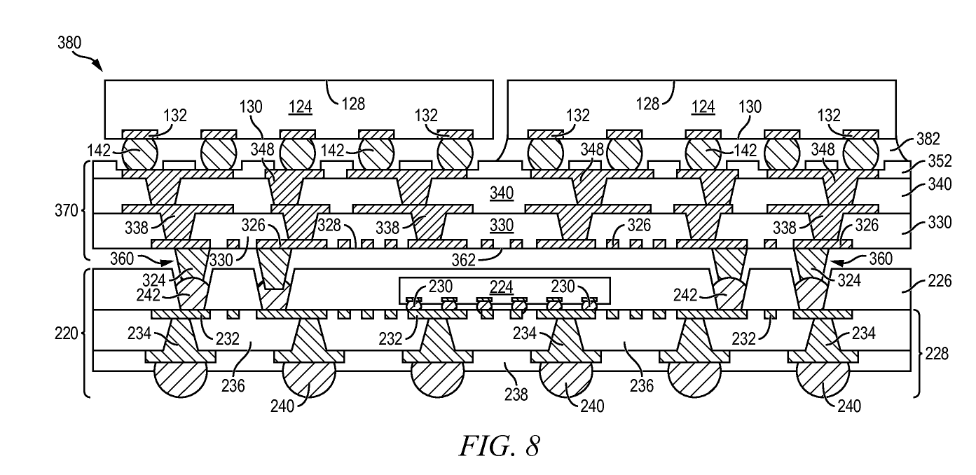

FIG. 8 illustrates, in relation to FIGS. 1, 2a-2e, and 6a-6l, another semiconductor package including a conductive column substrate. Continuing from FIG. 6l, FIG. 8 shows semiconductor die 124 from FIG. 2e disposed over conductive column substrate 370. Semiconductor die 124 are mounted to conductive column substrate 370 with bumps 142 oriented toward conductive column substrate 370.

Semiconductor die 124 is mounted to conductive column substrate 370 with bumps 142 electrically connected to conductive layer 348 to form semiconductor device 380. An optional underfill material 382, such as epoxy resin, disposed under semiconductor die 124 and around bumps 142. Semiconductor device 380 comprises a package-on-package interposer device including conductive column substrate 370 disposed between semiconductor die 124 and semiconductor package 220. Semiconductor die 124 are mounted to conductive column substrate 370 with bumps 142 metallurgically and electrically connected to conductive layer 348. Conductive column substrate 370 provides electrical interconnect for semiconductor die 124 to semiconductor package 220 and to external devices. Semiconductor die 124 is electrically connected to external devices through bumps 142, conductive column substrate 370, and semiconductor package 220.

FIGS. 9a-9p illustrate, in relation to FIG. 1, another method of forming a substrate having conductive columns using a double-sided process. FIG. 9a shows a portion of substrate or carrier 400 containing temporary or sacrificial base material such as silicon, steel, germanium, gallium arsenide, indium phosphide, silicon carbide, resin, beryllium oxide, glass, or other suitable low-cost, rigid material for structural support. Carrier 400 can be organic or inorganic base material. In one embodiment, carrier 400 includes metal. An interface layer or double-sided tape 402a is formed over a surface 404 of carrier 400 as a temporary adhesive bonding film, etch-stop layer, or release layer. An interface layer or double-sided tape 402b is formed over a surface 406 of carrier 400 opposite surface 404. Interface layer 402b operates as a temporary adhesive bonding film, etch-stop layer, or release layer. Carrier 400 operates as a double-sided carrier.

An electrically conductive layer or metal sheet 410a is formed over surface 404 of carrier 400 and interface layer 402a using a metal deposition process such as Cu foil lamination, sputtering, electrolytic plating, electroless plating, or other suitable metal deposition process. Conductive layer 410a can be one or more layers of Al, Cu, Sn, Ni, Au, Ag, or other suitable electrically conductive material. In one embodiment, conductive layer 410a includes Cu or a Cu alloy.

An electrically conductive layer or metal sheet 410b is formed over surface 406 of carrier 400 and interface layer 402b using a metal deposition process such as Cu foil lamination, sputtering, electrolytic plating, electroless plating, or other suitable metal deposition process. Conductive layer 410b can be one or more layers of Al, Cu, Sn, Ni, Au, Ag, or other suitable electrically conductive material. In one embodiment, conductive layer 410b includes Cu or a Cu alloy.

FIG. 9b shows a double-sided carrier 400 including conductive layers 410a and 410b formed over opposing surfaces of carrier 400. A double-sided carrier 400 is used to form conductive column substrates on both surfaces 404 and 406 of carrier 400 in a double-sided process.

In FIG. 9c, an electrically conductive layer 412 is formed over surface 414 of conductive layer 410a using a metal deposition process such as PVD, CVD, sputtering, electrolytic plating, electroless plating, or other suitable metal deposition process. Conductive layer 412 can be one or more layers of Cu, Sn, Ni, Au, Ag, Ti, W, or other suitable electrically conductive material. In one embodiment, conductive layer 412 operates as a barrier layer and includes Au, Ni/Au, Ni, NiV, Pt, Pd, Ni/Pd/Au, TiW, or CrCu, or other suitable barrier metal. In one embodiment, conductive layer 412 is deposited by plating a conductive material within patterned openings of a photoresist layer.

An electrically conductive layer 416 is formed over conductive layer 412 using a metal deposition process such as PVD, CVD, sputtering, electrolytic plating, electroless plating, or other suitable metal deposition process. Conductive layer 416 can be one or more layers of Cu, Sn, Ni, Au, Ag, Ti, W, or other suitable electrically conductive material. In one embodiment, conductive layer 416 includes plated Cu. In one embodiment, conductive layer 416 is deposited by plating Cu in patterned openings of a photoresist layer.

In FIG. 9d, an insulating or dielectric layer 420 is formed over conductive layers 410a, 412, and 416 using PVD, CVD, lamination, printing, spin coating, spray coating, sintering, or thermal oxidation. Insulating layer 420 includes one or more layers of SiO2, Si3N4, SiON, Ta2O5, Al2O3, polymer dielectric resist with or without fillers or fibers, or other material having similar structural and dielectric properties.

In FIG. 9e, a portion of insulating layer 420 is removed to form openings 422 in insulating layer 420 and expose portions of conductive layer 416. Openings 422 are formed by etching, LDA using laser 424, or a patterning and developing process.

In FIG. 9f, an electrically conductive layer 428 is formed over insulating layer 420 within openings 422 and over conductive layer 416. Conductive layer 428 is formed using a patterning and metal deposition process such as printing, PVD, CVD, lamination, sputtering, electrolytic plating, electroless plating, or other suitable metal deposition process. Conductive layer 428 can be one or more layers of Al, Cu, Sn, Ni, Au, Ag, or other suitable electrically conductive material. In one embodiment, conductive layer 428 includes plated Cu. An optional seed layer is formed over insulating layer 420 within openings 422 prior to forming conductive layer 428. In one embodiment, conductive layer 428 is formed over the seed layer. The seed layer can be Ni, TaN, NiV, Pt, Pd, CrCu, or other suitable barrier or seed material. Conductive layer 428 operates as an RDL to provide horizontal interconnection along insulating layer 420 and vertical interconnection through openings 422 in insulating layer 420. A portion of conductive layer 428 is electrically connected to conductive layers 412 and 416. Other portions of conductive layer 428 can be electrically common or electrically isolated.

In FIG. 9g, an insulating or passivation layer 430 is formed over conductive layer 428 and insulating layer 420 using PVD, CVD, printing, spin coating, spray coating, sintering or thermal oxidation. Insulating layer 430 contains one or more layers of solder resist, SiO2, Si3N4, SiON, Ta2O5, Al2O3, or other material having similar insulating and structural properties. Conductive layers 412, 416, and 428 and insulating layers 420 and 430 together constitute a build-up interconnect structure formed over conductive layer 410a.

In FIG. 9h, a process of forming insulating layers and conductive layers is repeated over conductive layer 410b. An electrically conductive layer 440 is formed over surface 442 of conductive layer 410b using a metal deposition process such as PVD, CVD, sputtering, electrolytic plating, electroless plating, or other suitable metal deposition process. Conductive layer 440 can be one or more layers of Cu, Sn, Ni, Au, Ag, Ti, W, or other suitable electrically conductive material. In one embodiment, conductive layer 440 operates as a barrier layer and includes Au, Ni/Au, Ni, NiV, Pt, Pd, Ni/Pd/Au, TiW, or CrCu, or other suitable barrier metal. In one embodiment, conductive layer 440 is deposited by plating a conductive material within patterned openings of a photoresist layer.

An electrically conductive layer 444 is formed over conductive layer 440 using a metal deposition process such as PVD, CVD, sputtering, electrolytic plating, electroless plating, or other suitable metal deposition process. Conductive layer 444 can be one or more layers of Cu, Sn, Ni, Au, Ag, Ti, W, or other suitable electrically conductive material. In one embodiment, conductive layer 444 includes plated Cu. In one embodiment, conductive layer 444 is deposited by plating Cu in patterned openings of a photoresist layer.

In FIG. 9i, an insulating or dielectric layer 450 is formed over conductive layers 410b, 440, and 444 using PVD, CVD, lamination, printing, spin coating, spray coating, sintering, or thermal oxidation. Insulating layer 450 includes one or more layers of SiO2, Si3N4, SiON, Ta2O5, Al2O3, polymer dielectric resist with or without fillers or fibers, or other material having similar structural and dielectric properties.

In FIG. 9j, a portion of insulating layer 450 is removed to form openings 452 in insulating layer 450 and expose portions of conductive layer 444. Openings 452 are formed by etching, LDA using laser 454, or a patterning and developing process.

In FIG. 9k, an electrically conductive layer 458 is formed over insulating layer 450 within openings 452 and over conductive layer 444. Conductive layer 458 is formed using a patterning and metal deposition process such as printing, PVD, CVD, lamination, sputtering, electrolytic plating, electroless plating, or other suitable metal deposition process. Conductive layer 458 can be one or more layers of Al, Cu, Sn, Ni, Au, Ag, or other suitable electrically conductive material. In one embodiment, conductive layer 458 includes plated Cu. An optional seed layer is formed over insulating layer 450 within openings 452 prior to forming conductive layer 458. In one embodiment, conductive layer 458 is formed over the seed layer. The seed layer can be Ni, TaN, NiV, Pt, Pd, CrCu, or other suitable barrier or seed material. Conductive layer 458 operates as an RDL to provide horizontal interconnection along insulating layer 450 and vertical interconnection through openings 452 in insulating layer 450. A portion of conductive layer 458 is electrically connected to conductive layers 440 and 444. Other portions of conductive layer 458 can be electrically common or electrically isolated.

In FIG. 9l, an insulating or passivation layer 460 is formed over conductive layer 458 and insulating layer 450 using PVD, CVD, printing, spin coating, spray coating, sintering or thermal oxidation. Insulating layer 460 contains one or more layers of solder resist, SiO2, Si3N4, SiON, Ta2O5, Al2O3, or other material having similar insulating and structural properties. Conductive layers 440, 444, and 458 and insulating layers 450 and 460 together constitute a build-up interconnect structure formed over conductive layer 410b.

In FIG. 9m, conductive layers 410a and 410b are separated from carrier 400 and interface layers 402a and 402b. Carrier 400 and interface layers 402a and 402b are removed by chemical etching, mechanical peeling, CMP, mechanical grinding, thermal bake, UV light, laser scanning, or wet stripping to expose conductive layers 410a and 410b. In one embodiment, conductive layers 410a and 410b are separated from carrier 400 by debonding interface layers 402a and 402b. In one embodiment, interface layers 402a and 402b are thermally releasable layers that are thermally activated to separate panels 470 and 472. After carrier 400 and interface layers 402a and 402b are removed, the double-sided substrate panel is separated into two substrate panels 470 and 472. After interface layers 402a and 402b are removed, surface 474 of conductive layer 410a is exposed, and surface 476 of conductive layer 410b is exposed.

In FIG. 9n, a portion of conductive layer 410b is removed by an etching process to leave individual conductive columns or pillars 480. Portions of conductive layer 410b are removed to expose conductive layer 440 and insulating layer 450 at surface 482. Conductive pillars 480 are electrically connected to conductive layers 440, 444, and 458. Conductive pillars 480 can be formed with any shape and height. Conductive pillars 480 can have a cylindrical shape with a circular or oval cross-section, or conductive pillars 480 can have a cubic shape with a rectangular cross-section. In one embodiment, conductive pillars 480 include a height of 100 μm or greater. In another embodiment, conductive pillars 480 include a height of less than 100 μm. A similar process of etching conductive layer 410b is repeated for conductive layer 410a on substrate panel 470. Portions of conductive layer 410a are etched to form conductive pillars, similar to conductive pillars 480. Thus, a plurality of substrate panels including conductive pillars are formed using a double-sided process.

In FIG. 9o, a portion of insulating layer 460 is removed by a patterning and developing process to form openings 484 and to expose portions of conductive layer 458. The exposed conductive layer 458 can be treated with an OSP, Ni/Au, Ni/Pd/Au, Sn, or other suitable material. Conductive layers 440, 444, and 458, together with conductive pillars 480 and insulating layers 450 and 460 form a conductive column substrate 490. Conductive column substrate 490 is singulated through insulating layers 450 and 460 to form individual units of conductive column substrate 490. By forming interconnect substrates over both surfaces of carrier 400, the cost of forming conductive column substrates 490 is further reduced.

Conductive column substrate 490 contains one or more insulating or dielectric layers. Conductive column substrate 490 also contains one or more conductive layers operating as RDLs to provide electrical interconnect laterally and vertically through conductive column substrate 490. Conductive column substrate 490 provides electrical interconnect between a first surface of conductive column substrate 490 to a second surface opposite the first surface. Conductive column substrate 490 is used as an interposer for vertical or stacked semiconductor device integration. Conductive pillars 480 are electrically connected through conductive layers 440 and 444 to conductive layer 458. Conductive column substrate 480 provides interconnection for additional devices mounted over conductive layer 458 and for additional devices mounted over conductive pillars 480. Etching conductive layer 410b reduces the need for expensive plating materials in the process of forming conductive pillars 480. The process of forming conductive pillars 480 by etching conductive layer 410b reduces the cost of forming conductive pillars 480 over an interposer, such as conductive column substrate 490. Additionally, conductive pillars 480 formed by etching can have a greater height than conductive pillars formed by other processing methods, such as plating.

FIG. 9p shows a process of disposing conductive column substrate 490 over a semiconductor package 220. Semiconductor package 220 comprises a PoPb device. In one embodiment, semiconductor package 220 includes an eWLB PoPb device including interconnections outside a footprint of semiconductor die 224. Semiconductor package 220 includes semiconductor die 224 surrounded by encapsulant 226. Interconnect structure 228 is formed over semiconductor die 224 and encapsulant 226. Semiconductor die 224 is electrically connected to interconnect structure 228 through bumps 230. In one embodiment, interconnect structure 228 includes a build-up interconnect structure including conductive layers 232 and 234, insulating layers 236 and 238, and bumps 240. Build-up interconnect structure 228 includes an electrically conductive layer or RDL 232 formed using a patterning and metal deposition process such as sputtering, electrolytic plating, and electroless plating. Conductive layer 232 can be one or more layers of Al, Cu, Sn, Ni, Au, Ag, or other suitable electrically conductive material.

Build-up interconnect structure 228 further includes an insulating or passivation layer 236 formed between conductive layer 232 for electrical isolation using PVD, CVD, printing, spin coating, spray coating, sintering or thermal oxidation. Insulating layer 236 contains one or more layers of SiO2, Si3N4, SiON, Ta2O5, Al2O3, or other material having similar insulating and structural properties. A portion of insulating layer 236 is removed by etching, LDA, or a patterning and developing process to form openings to expose conductive layer 232.

An electrically conductive layer 234 is formed over conductive layer 232 using a deposition process such as sputtering, electrolytic plating, or electroless plating. Conductive layer 234 can be one or more layers of Al, Cu, Sn, Ni, Au, Ag, or other suitable electrically conductive material. Conductive layers 232 and 234 operate as RDLs.

An insulating or passivation layer 238 is formed over insulating layer 236 and conductive layer 234 using PVD, CVD, printing, lamination, spin coating, or spray coating. Insulating layer 238 contains one or more layers of SiO2, Si3N4, SiON, Ta2O5, Al2O3, solder resist, or other material having similar insulating and structural properties. A portion of insulating layer 238 is removed by etching, LDA, or a patterning and developing process to expose conductive layer 234.

An electrically conductive bump material is deposited over build-up interconnect structure 228 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 234 using a suitable attachment or bonding process. In one embodiment, the bump material is reflowed by heating the material above its melting point to form balls or bumps 240. In some applications, bumps 240 are reflowed a second time to improve electrical contact to conductive layer 234. A UBM layer can be formed under bumps 240. Bumps 240 can also be compression bonded to conductive layer 234. Bumps 240 represent one type of interconnect structure that can be formed over conductive layer 234. The interconnect structure can also use bond wires, stud bump, micro bump, or other electrical interconnect.

Semiconductor package 220 includes recessed vertical interconnects or bumps 242 to accommodate stacked semiconductor devices in a PoP arrangement. Openings 244 are formed through a surface of encapsulant 226 opposite interconnect structure 228 Bumps 242 are recessed within openings 244 of encapsulant 226. Openings 244 accommodate conductive pillars 480.

Conductive column substrate 490 is mounted over semiconductor package 220 with conductive pillars 480 oriented toward semiconductor package 220. Conductive pillars 480 align with openings 244 and are disposed within openings 244 to electrically connect to bumps 242. Semiconductor die 224 is electrically connected to conductive column substrate 490 through bumps 230, interconnect structure 228, bumps 242, and conductive pillars 480. Conductive column substrate 490 provides electrical interconnection to external devices through conductive pillars 480, bumps 242, interconnect structure 228, and bumps 240. Conductive pillars 480 provide a vertical interconnect with a height that extends to into openings of a PoPb package for stacked PoP configurations. Conductive pillars 480 of conductive column substrate 490 disposed within openings 244 reduces the height of the overall semiconductor package.

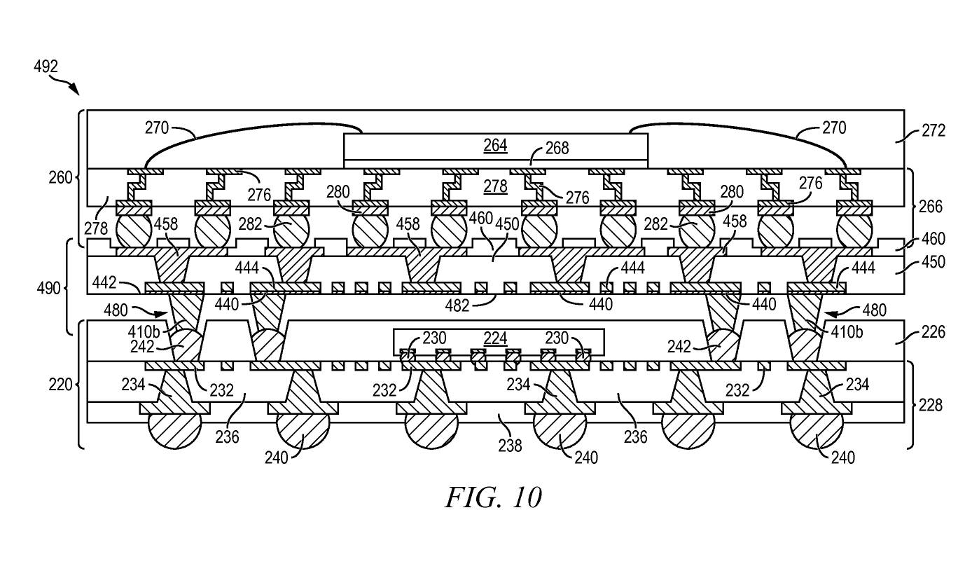

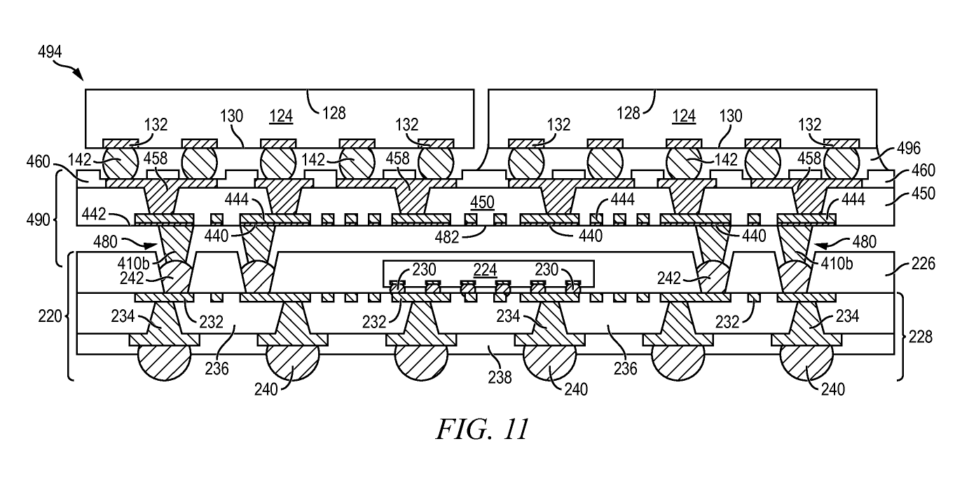

FIG. 10 illustrates, in relation to FIGS. 1 and 9a-9p, a semiconductor package including a conductive column substrate. Continuing from FIG. 9p, FIG. 10 shows semiconductor package 260 disposed over conductive column substrate 490. Semiconductor package 260 comprises a PoPt device. Semiconductor die 264 is mounted to substrate or interposer 266 using die attach adhesive 268, such as epoxy resin. Bond wires 270 are formed between interposer 266 and contact pads on an active surface of semiconductor die 264. An encapsulant 272 is deposited over semiconductor die 264, substrate 266, and bond wires 270. Interposer 266 includes one or more conductive layers 276 and one or more insulating or passivation layers 278. Conductive layer 276 provides vertical and horizontal conduction paths through interposer 266. Portions of conductive layers 276 are electrically common or electrically isolated according to the design and function of the semiconductor die to be mounted to interposer 266.

An electrically conductive layer 280 is formed over conductive layer 276 using a deposition process such as sputtering, electrolytic plating, or electroless plating. Conductive layer 280 can be Al, Cu, Sn, Ni, Au, Ag, or other suitable electrically conductive material. Conductive layer 280 is a UBM electrically connected to conductive layer 276. UBMs 280 can be a multi-metal stack with adhesion layer, barrier layer, and seed or wetting layer. The adhesion layer is formed over conductive layer 276 and can be Ti, TiN, TiW, Al, or Cr. The barrier layer is formed over the adhesion layer and can be Au, Ni/Au, Ni, NiV, Pt, Pd, Ni/Pd/Au, TiW, or CrCu. The barrier layer inhibits the diffusion of Cu into the active area of the die. The seed layer is formed over the barrier layer and can be Cu, Ni, TaN, NiV, Au, CrCu, or Al. UBMs 280 provide a low resistive interconnect to conductive layer 276, as well as a barrier to solder diffusion and seed layer for solder wettability.

An electrically conductive bump material is deposited over a surface of interposer 266 opposite semiconductor die 264 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 280 using a suitable attachment or bonding process. In one embodiment, the bump material is reflowed by heating the material above its melting point to form balls or bumps 282. In some applications, bumps 282 are reflowed a second time to improve electrical contact to conductive layer 280. Bumps 282 can also be compression bonded to conductive layer 280. Bumps 282 represent one type of interconnect structure that can be formed over interposer 266. The interconnect structure can also use bond wires, stud bump, micro bump, or other electrical interconnect.

Semiconductor package 260 is disposed over conductive column substrate 490 with bumps 282 oriented toward conductive column substrate 490. Semiconductor package 260 is mounted over conductive column substrate 490 to form semiconductor device 492. Semiconductor device 492 comprises a package-on-package interposer device including conductive column substrate 490 disposed between semiconductor package 260 and semiconductor package 220. Semiconductor package 260 is mounted to conductive column substrate 490 with bumps 282 metallurgically and electrically connected to conductive layer 458. Conductive column substrate 490 provides electrical interconnect for semiconductor package 260 to semiconductor package 220 and to external devices. Semiconductor die 264 is electrically connected to external devices through wire bonds 270, interposer 266, UBM 280, bumps 282, conductive column substrate 490, and semiconductor package 220.

FIG. 11 illustrates, in relation to FIGS. 1, 2a-2e, and 9a-9p, another semiconductor package including a conductive column substrate. Continuing from FIG. 9p, FIG. 11 shows semiconductor die 124 from FIG. 2e disposed over conductive column substrate 490. Semiconductor die 124 are mounted to conductive column substrate 490 with bumps 142 oriented toward conductive column substrate 490.

Semiconductor die 124 is mounted to conductive column substrate 490 with bumps 142 electrically connected to conductive layer 458 to form semiconductor device 494. An optional underfill material 496, such as epoxy resin, disposed under semiconductor die 124 and around bumps 142. Semiconductor device 494 comprises a package-on-package interposer device including conductive column substrate 490 disposed between semiconductor die 124 and semiconductor package 220. Semiconductor die 124 are mounted to conductive column substrate 490 with bumps 142 metallurgically and electrically connected to conductive layer 458. Conductive column substrate 490 provides electrical interconnect for semiconductor die 124 to semiconductor package 220 and to external devices. Semiconductor die 124 is electrically connected to external devices through bumps 142, conductive column substrate 490, and semiconductor package 220.

While one or more embodiments of the present invention have been illustrated in detail, the skilled artisan will appreciate that modifications and adaptations to those embodiments may be made without departing from the scope of the present invention as set forth in the following claims.

1. A method of making a semiconductor device, comprising:
providing a first conductive layer;
forming a second conductive layer over a first surface of the first conductive layer;
forming a first insulating layer over the first and second conductive layers; and
removing a portion of the first conductive layer from a second surface opposite the first surface to form a plurality of conductive pillars.

2. The method of claim 1, further including removing the portion of the first conductive layer using an etching process.

3. The method of claim 1, further including disposing the conductive pillars over a semiconductor package.

4. The method of claim 1, further including:
forming a third conductive layer over the first insulating layer; and
forming a second insulating layer over the third conductive layer.

5. The method of claim 1, further including:
removing a portion of the first insulating layer to form an opening over the second conductive layer; and
forming a third conductive layer within the opening over the second conductive layer.

6. The method of claim 1, further including disposing a semiconductor die over the first surface of the first conductive layer.

7. A method of making a semiconductor device, comprising:
providing a first conductive layer;
forming a second conductive layer over the first conductive layer;
forming a first insulating layer over the second conductive layer; and
removing a portion of the first conductive layer to form a conductive pillar.

8. The method of claim 7, further including removing the portion of the first conductive layer using an etching process.

9. The method of claim 7, further including:
forming a third conductive layer over the first insulating layer; and
forming a second insulating layer over the third conductive layer.

10. The method of claim 7, wherein the conductive pillar includes a height of 100 micrometers (μm) or greater.

11. The method of claim 7, further including:
disposing the first conductive layer over a carrier;
forming the second conductive layer and first insulating layer over the first conductive layer while disposed on the carrier; and
removing the carrier to expose the first conductive layer prior to removing the portion of the first conductive layer.

12. The method of claim 7, further including:
disposing a first semiconductor package over a first surface of the first conductive layer; and
disposing a second semiconductor package over a second surface of the first conductive layer.

13. The method of claim 7, further including disposing a semiconductor die over the first conductive layer.

14. A method of making a semiconductor device, comprising:
providing a first conductive layer;
forming a second conductive layer over the first conductive layer; and
removing a portion of the first conductive layer to form a conductive pillar.

15. The method of claim 14, further including removing the portion of the first conductive layer using an etching process.

16. The method of claim 14, further including:
forming a first insulating layer over the second conductive layer; and
forming the second conductive layer over the first insulating layer electrically connected to the first conductive layer.

17. The method of claim 16, further including:
forming a second insulating layer over the first conductive layer; and
forming a third conductive layer over the second insulating layer electrically connected to the second conductive layer.

18. The method of claim 14, further including disposing the conductive pillar over a semiconductor package.

19. The method of claim 14, further including disposing a semiconductor die over the first conductive layer.

20. A semiconductor device, comprising:
a first conductive layer;
a first insulating layer formed over a first surface of the first conductive layer; and
a conductive pillar formed over a second surface of the first conductive layer opposite the first surface.

21. The semiconductor device of claim 20, wherein the conductive pillar includes a height of 100 micrometers (μm) or greater.

22. The semiconductor device of claim 20, further including:
a second conductive layer formed over the first insulating layer; and
a second insulating layer formed over the second conductive layer and first insulating layer.

23. The semiconductor device of claim 22, further including:
a third conductive layer formed over the second insulating layer; and
a third insulating layer formed over the third conductive layer and second insulating layer.

24. The semiconductor device of claim 20, further including a semiconductor die disposed over the first surface of the first conductive layer.

25. The semiconductor device of claim 20, further including:
a first semiconductor package disposed over the first surface of the first conductive layer; and
a second semiconductor package disposed over the second surface of the first conductive layer.
